(19) United States
(12) Patent Application Publication
(10) Pub. No.: US 2025/0366369 A1
(43) Pub. Date: Nov. 27, 2025

(54) THERMOELECTROMOTIVE FORCE GENERATING ELEMENT, METHOD OF PRODUCING A THERMOELECTROMOTIVE FORCE GENERATING ELEMENT, AND IMAGE SENSOR

(71) Applicant: Sony Group Corporation, Tokyo (JP)

(72) Inventors: Koji KADONO, Tokyo (JP); Shinji IMAIZUMI, Tokyo (JP); Taishi ANO, Tokyo (JP)

(21) Appl. No.: 18/577,102

(22) PCT Filed: Jul. 6, 2022
(86) PCT No.: PCT/JP2022/026787

§ 371 Date: Jan. 5, 2024

(30) Foreign Application Priority Data
Jul. 7, 2021 (JP) 2021-112679

(51) Int. Cl. H10N 10/17; H10N 10/01; H10N 10/851

(52) U.S. Cl. CPC H10N 10/17; H10N 10/01; H10N 10/851

(57) ABSTRACT

To provide a thermoelectromotive force generating element capable of generating thermoelectromotive force with high efficiency while maintaining strength even when the element is miniaturized.

A thermoelectromotive force generating element 10 includes: a substrate 11; a thermoelectric conversion layer 12 that is stacked on the substate and includes a P-type thermoelectric material 21 and an N-type thermoelectric material 22; a first electrode 13 on a low temperature side connected to one end of the thermoelectric conversion layer; a second electrode 14 on a high temperature side connected to the other end of the thermoelectric conversion layer; and an absorption portion 15 that is stacked in contact with the second electrode and absorbs heat received from outside, the P-type thermoelectric material and the N-type thermoelectric material forming a PN series connection.

### TECHNICAL FIELD

The present technology relates to a technology of a thermoelectromotive force generating element and more specifically a thermoelectromotive force generating element including an absorption layer that absorbs heat received from the outside such as light and a thermoelectric conversion layer that includes a P-type thermoelectric material that uses holes as carriers during heat generation and an N-type thermoelectric material that uses electrons as carriers during heat generation and coverts a temperature change in the absorption layer into an electrical signal, a method of producing the thermoelectromotive force generating element, and an image sensor.

### BACKGROUND ART

In the past, a thermoelectric conversion element that generates thermoelectromotive force by electrically connecting thermoelectric elements formed of a P-type thermoelectric material and an N-type thermoelectric material has been known. For example, a thermal detection element that functions as a sensor that outputs a module temperature change as an electrical signal to the outside and a thermoelectric conversion element that converts thermal energy into electrical energy using the Seebeck effect of a material have been known.

As an example of such an element that generates thermoelectromotive force, Patent Literature 1 proposes a thermoelectric conversion module that electrically connects a plurality of thermoelectric elements in series by connecting the end portions of adjacent thermoelectric elements with a conductive material, in which a space between the thermoelectric elements is filled with an insulation resin to fix the thermoelectric elements to each other with the resin and an insulation layer whose outer surface is coated with a metal is provided on the side of the end portions of the thermoelectric elements on which the conductive material is disposed.

### CITATION LIST

### Patent Literature

Patent Literature 1: Japanese Patent Application Laid-open No. 2001-119076

### DISCLOSURE OF INVENTION

### Technical Problem

However, while a thermoelectric conversion element such as one disclosed in Patent Literature 1 is used to extract thermal energy near room temperature, including detection of infrared rays, the thermoelectromotive force, thermoelectric conversion efficiency, response speed, and miniaturization of the element are not sufficient, and the practical range has been limited.

Further, a structure in which a P-type thermoelectric conversion material and an N-type thermoelectric conversion material with a high aspect ratio are alternately electrically connected in series to obtain thermoelectromotive force from infrared rays and heat with high efficiency is referred to as a PN series connection. In this method, it is difficult to arrange thermoelectric materials having different polarities adjacent to each other in three dimensions. Further, with miniaturization, measures are taken to ensure strength by using an insulation mold, but efficiency deteriorates due to solid heat diffusion. For example, in an infrared detection element, measures are taken to provide a gap around a thermoelectric material, which makes the miniaturization difficult.

In this regard, it is a main object of the present technology to provide a thermoelectromotive force generating element capable of generating thermoelectromotive force with high efficiency while maintaining strength even when the element is miniaturized.

### Solution to Problem

A thermoelectromotive force generating element according to the present technology includes: a substrate; a thermoelectric conversion layer that is stacked on the substate and includes a P-type thermoelectric material and an N-type thermoelectric material; a first electrode on a low temperature side connected to one end of the thermoelectric conversion layer; a second electrode on a high temperature side connected to the other end of the thermoelectric conversion layer; and an absorption portion that is stacked in contact with the second electrode and absorbs heat received from outside, the P-type thermoelectric material and the N-type thermoelectric material forming a PN series connection. That is, the high temperature side is a side that becomes high temperature when a temperature difference occurs due to heat received from the outside by infrared rays or the like, and the low temperature side is a side that is kept at a low temperature using the substrate as a cold bath (heat sink).

Further, a method of producing a thermoelectromotive force generating element according to the present technology includes: a step of forming a substrate; a step of forming a first electrode on a low temperature side such that the first electrode is in contact with the substrate; a step of stacking a thermoelectric conversion layer that includes a P-type thermoelectric material and an N-type thermoelectric material such that the thermoelectric conversion layer is connected to the first electrode; a step of forming a second electrode on a high temperature side such that the second electrode is connected to the other end of the thermoelectric conversion layer; and a step of stacking an absorption layer that absorbs heat received from outside such that the absorption layer is in contact with the second electrode, the P-type thermoelectric material and the N-type thermoelectric material forming a PN series connection. Note that the order of the Steps descried above is not limited, and can be changed as appropriate. Further, in the method of producing a thermoelectromotive force generating element according to the present technology, “forming . . . in contact with”, “stacking connected to”, “forming . . . connected to”, or “stacking . . . in contact with” is not limited to a case where a target object and an object are formed in contact with each other and includes a case where an object and a target object are replaced from each other and formed. For example, “forming a first electrode on a low temperature side such that the first electrode is in contact with the substrate” refers to that the first electrode and the substrate are formed in contact with each other and includes both a case of forming a first electrode such that the first electrode is in contact with a substrate and a case of forming a substrate such that the substrate is in contact with a first electrode.

Further, a thermoelectromotive force generating element according to the present technology can be used as an image sensor including a plurality of the thermoelectric conversion element, the plurality of thermoelectromotive force generating elements being arrayed.

### Advantageous Effects of Invention

In accordance with the present technology, it is possible to provide a thermoelectromotive force generating element capable of generating thermoelectromotive force with high efficiency while maintaining strength even when the element is miniaturized. Note that the above effects are not necessarily limitative, and any of the effects shown in the present specification or other effects that can be understood from the present specification may be exhibited in addition to or instead of the above effects.

### BRIEF DESCRIPTION OF DRAWINGS

FIG. 1 is a schematic diagram showing a configuration example of a thermoelectric conversion element according to a first embodiment of the present technology.

FIG. 2 is a side cross-sectional view showing the configuration example of the thermoelectric conversion element according to the first embodiment of the present technology.

FIG. 3 is a plan cross-sectional view showing the configuration example of the thermoelectric conversion element according to the first embodiment of the present technology.

FIG. 4 is a side cross-sectional view showing a modified example of the thermoelectric conversion element according to the first embodiment of the present technology.

FIG. 5 is a plan cross-sectional view showing a modified example of the thermoelectric conversion element according to the first embodiment of the present technology.

FIG. 6 is an enlarged schematic diagram showing a modified example of the thermoelectric conversion element according to the first embodiment of the present technology.

FIG. 7 is a schematic diagram showing a method of producing the thermoelectric conversion element according to the first embodiment of the present technology.

FIG. 8 is a schematic diagram showing an example of the method of producing the thermoelectric conversion element according to the first embodiment of the present technology.

FIG. 9 is a schematic diagram showing an example of the method of producing the thermoelectric conversion element according to the first embodiment of the present technology.

FIG. 10 is a schematic diagram showing an example of the method of producing the thermoelectric conversion element according to the first embodiment of the present technology.

FIG. 11 is a schematic diagram showing an example of the method of producing the thermoelectric conversion element according to the first embodiment of the present technology.

FIG. 12 is a schematic diagram showing an example of the method of producing the thermoelectric conversion element according to the first embodiment of the present technology.

FIG. 13 is a schematic diagram showing an example of the method of producing the thermoelectric conversion element according to the first embodiment of the present technology.

FIG. 14 is a schematic diagram showing an example of the method of producing the thermoelectric conversion element according to the first embodiment of the present technology.

FIG. 15 is a schematic diagram showing an example of the method of producing the thermoelectric conversion element according to the first embodiment of the present technology.

FIG. 16 is a schematic diagram showing an example of the method of producing the thermoelectric conversion element according to the first embodiment of the present technology.

FIG. 17 is a schematic diagram showing an example of the method of producing the thermoelectric conversion element according to the first embodiment of the present technology.

FIG. 18 is a schematic diagram showing an example of the method of producing the thermoelectric conversion element according to the first embodiment of the present technology.

FIG. 19 is a schematic diagram showing an example of the method of producing the thermoelectric conversion element according to the first embodiment of the present technology.

FIG. 20 is a schematic diagram showing an example of the method of producing the thermoelectric conversion element according to the first embodiment of the present technology.

FIG. 21 is a schematic diagram showing an example of the method of producing the thermoelectric conversion element according to the first embodiment of the present technology.

FIG. 22 is a schematic diagram showing an example of a method of producing a modified example of the thermoelectric conversion element according to the first embodiment of the present technology.

FIG. 23 is a schematic diagram showing a modified example of the method of producing the thermoelectric conversion element according to the first embodiment of the present technology.

FIG. 24 is a schematic diagram showing the modified example of the method of producing the thermoelectric conversion element according to the first embodiment of the present technology.

FIG. 25 is a schematic diagram showing the modified example of the method of producing the thermoelectric conversion element according to the first embodiment of the present technology.

FIG. 26 is a schematic diagram showing the modified example of the method of producing the thermoelectric conversion element according to the first embodiment of the present technology.

FIG. 27 is a side cross-sectional view showing a configuration example of a thermoelectric conversion element according to a second embodiment of the present technology.

FIG. 28 is a side cross-sectional view showing a configuration example of a thermoelectric conversion element according to a third embodiment of the present technology.

FIG. 29 is a plan cross-sectional view showing a configuration example of the thermoelectric conversion element according to the third embodiment of the present technology.

FIG. 30 is a side cross-sectional view showing a modified example of the thermoelectric conversion element according to the third embodiment of the present technology.

FIG. 31 is a schematic diagram showing an example of a method of producing the thermoelectric conversion element according to the third embodiment of the present technology.

FIG. 32 is a schematic diagram showing an example of the method of producing the thermoelectric conversion element according to the third embodiment of the present technology.

FIG. 33 is a schematic diagram showing an example of the method of producing the thermoelectric conversion element according to the third embodiment of the present technology.

FIG. 34 is a schematic diagram showing an example of the method of producing the thermoelectric conversion element according to the third embodiment of the present technology.

FIG. 35 is a schematic diagram showing an example of the method of producing the thermoelectric conversion element according to the third embodiment of the present technology.

FIG. 36 is a schematic diagram showing an example of the method of producing the thermoelectric conversion element according to the third embodiment of the present technology.

FIG. 37 is a schematic diagram showing an example of the method of producing the thermoelectric conversion element according to the third embodiment of the present technology.

FIG. 38 is a schematic diagram showing an example of the method of producing the thermoelectric conversion element according to the third embodiment of the present technology.

FIG. 39 is a schematic diagram showing an example of the method of producing the thermoelectric conversion element according to the third embodiment of the present technology.

FIG. 40 is a schematic diagram showing an example of the method of producing the thermoelectric conversion element according to the third embodiment of the present technology.

FIG. 41 is a schematic diagram showing a modified example of the method of producing the thermoelectric conversion element according to the third embodiment of the present technology.

FIG. 42 is a schematic diagram showing the modified example of the method of producing the thermoelectric conversion element according to the third embodiment of the present technology.

FIG. 43 is a schematic diagram showing the modified example of the method of producing the thermoelectric conversion element according to the third embodiment of the present technology.

FIG. 44 is a schematic diagram showing the modified example of the method of producing the thermoelectric conversion element according to the third embodiment of the present technology.

FIG. 45 is a schematic diagram showing the modified example of the method of producing the thermoelectric conversion element according to the third embodiment of the present technology.

FIG. 46 is a schematic diagram showing the modified example of the method of producing the thermoelectric conversion element according to the third embodiment of the present technology.

FIG. 47 is a schematic diagram showing the modified example of the method of producing the thermoelectric conversion element according to the third embodiment of the present technology.

FIG. 48 is a schematic diagram showing the modified example of the method of producing the thermoelectric conversion element according to the third embodiment of the present technology.

FIG. 49 is a schematic diagram showing the modified example of the method of producing the thermoelectric conversion element according to the third embodiment of the present technology.

FIG. 50 is a schematic diagram showing an example of a method of producing a thermoelectric conversion element according to a fourth embodiment of the present technology.

FIG. 51 is a schematic diagram showing an example of the method of producing the thermoelectric conversion element according to the fourth embodiment of the present technology.

FIG. 52 is a schematic diagram showing an example of the method of producing the thermoelectric conversion element according to the fourth embodiment of the present technology.

FIG. 53 is a schematic diagram showing an example of the method of producing the thermoelectric conversion element according to the fourth embodiment of the present technology.

FIG. 54 is a schematic diagram showing an example of the method of producing the thermoelectric conversion element according to the fourth embodiment of the present technology.

FIG. 55 is a schematic diagram showing an example of the method of producing the thermoelectric conversion element according to the fourth embodiment of the present technology.

FIG. 56 is a schematic diagram showing an example of the method of producing the thermoelectric conversion element according to the fourth embodiment of the present technology.

FIG. 57 is a schematic diagram showing an example of the method of producing the thermoelectric conversion element according to the fourth embodiment of the present technology.

FIG. 58 is a schematic diagram showing an example of the method of producing the thermoelectric conversion element according to the fourth embodiment of the present technology.

FIG. 59 is a schematic diagram showing an example of the method of producing the thermoelectric conversion element according to the fourth embodiment of the present technology.

FIG. 60 is a schematic diagram showing an example of the method of producing the thermoelectric conversion element according to the fourth embodiment of the present technology.

FIG. 61 is a schematic diagram showing an example of the method of producing the thermoelectric conversion element according to the fourth embodiment of the present technology.

FIG. 62 is a schematic diagram showing an example of the method of producing the thermoelectric conversion element according to the fourth embodiment of the present technology.

FIG. 63 is a schematic diagram showing an example of the method of producing the thermoelectric conversion element according to the fourth embodiment of the present technology.

FIG. 64 is a schematic diagram showing an example of the method of producing the thermoelectric conversion element according to the fourth embodiment of the present technology.

FIG. 65 is a schematic diagram showing an example of the method of producing the thermoelectric conversion element according to the fourth embodiment of the present technology.

FIG. 66 is a schematic diagram showing an example of the method of producing the thermoelectric conversion element according to the fourth embodiment of the present technology.

FIG. 67 is a schematic diagram showing an example of the method of producing the thermoelectric conversion element according to the fourth embodiment of the present technology.

FIG. 68 is a schematic diagram showing an example of the method of producing the thermoelectric conversion element according to the fourth embodiment of the present technology.

FIG. 69 is a schematic diagram showing an example of the method of producing the thermoelectric conversion element according to the fourth embodiment of the present technology.

FIG. 70 is a schematic diagram showing an example of the method of producing the thermoelectric conversion element according to the fourth embodiment of the present technology.

FIG. 71 is a schematic diagram showing an example of the method of producing the thermoelectric conversion element according to the fourth embodiment of the present technology.

FIG. 72 is a schematic diagram showing an example of the method of producing the thermoelectric conversion element according to the fourth embodiment of the present technology.

FIG. 73 is a schematic diagram showing an example of the method of producing the thermoelectric conversion element according to the fourth embodiment of the present technology.

FIG. 74 is a schematic diagram showing an example of the method of producing the thermoelectric conversion element according to the fourth embodiment of the present technology.

FIG. 75 is a schematic diagram showing an example of the method of producing the thermoelectric conversion element according to the fourth embodiment of the present technology.

FIG. 75 is a schematic diagram showing an example of the method of producing the thermoelectric conversion element according to the fourth embodiment of the present technology.

FIG. 77 is a schematic diagram showing a modified example of a method of producing the thermoelectric conversion element according to the fourth embodiment of the present technology.

FIG. 78 is a schematic diagram showing a modified example of the method of producing the thermoelectric conversion element according to the fourth embodiment of the present technology.

FIG. 79 is a schematic diagram showing a modified example of the method of producing the thermoelectric conversion element according to the fourth embodiment of the present technology.

FIG. 80 is a schematic diagram showing a modified example of the method of producing the thermoelectric conversion element according to the fourth embodiment of the present technology.

FIG. 81 is a schematic diagram showing a modified example of the method of producing the thermoelectric conversion element according to the fourth embodiment of the present technology.

FIG. 82 is a schematic diagram showing a modified example of the method of producing the thermoelectric conversion element according to the fourth embodiment of the present technology.

FIG. 83 is a schematic diagram showing a modified example of the method of producing the thermoelectric conversion element according to the fourth embodiment of the present technology.

FIG. 84 is a schematic diagram showing a modified example of the method of producing the thermoelectric conversion element according to the fourth embodiment of the present technology.

FIG. 85 is a schematic diagram showing a modified example of the method of producing the thermoelectric conversion element according to the fourth embodiment of the present technology.

FIG. 86 is a schematic diagram showing a modified example of the method of producing the thermoelectric conversion element according to the fourth embodiment of the present technology.

FIG. 87 is a schematic diagram showing a modified example of the method of producing the thermoelectric conversion element according to the fourth embodiment of the present technology.

FIG. 88 is a schematic diagram showing a modified example of the method of producing the thermoelectric conversion element according to the fourth embodiment of the present technology.

FIG. 89 is a schematic diagram showing a modified example of the method of producing the thermoelectric conversion element according to the fourth embodiment of the present technology.

FIG. 90 is a schematic diagram showing a modified example of the method of producing the thermoelectric conversion element according to the fourth embodiment of the present technology.

FIG. 91 is a schematic diagram showing a modified example of the method of producing the thermoelectric conversion element according to the fourth embodiment of the present technology.

FIG. 92 is a schematic diagram showing a modified example of the method of producing the thermoelectric conversion element according to the fourth embodiment of the present technology.

FIG. 93 is a schematic diagram showing a modified example of the method of producing the thermoelectric conversion element according to the fourth embodiment of the present technology.

FIG. 94 is a schematic diagram showing a modified example of the method of producing the thermoelectric conversion element according to the fourth embodiment of the present technology.

FIG. 95 is a schematic diagram showing a modified example of the method of producing the thermoelectric conversion element according to the fourth embodiment of the present technology.

FIG. 96 is a schematic diagram showing a modified example of the method of producing the thermoelectric conversion element according to the fourth embodiment of the present technology.

FIG. 97 is a schematic diagram showing a modified example of the method of producing the thermoelectric conversion element according to the fourth embodiment of the present technology.

FIG. 98 is a schematic diagram showing a modified example of the method of producing the thermoelectric conversion element according to the fourth embodiment of the present technology.

FIG. 99 is a schematic diagram showing a modified example of the method of producing the thermoelectric conversion element according to the fourth embodiment of the present technology.

FIG. 100 is a plan view showing a configuration example of the thermoelectric conversion element according to the fourth embodiment of the present technology.

FIG. 101 is an enlarged schematic diagram showing a configuration example of the thermoelectric conversion element according to the fourth embodiment of the present technology.

FIG. 102 is a side cross-sectional view showing a modified example of the thermoelectric conversion element according to the fourth embodiment of the present technology.

### MODE(S) FOR CARRYING OUT THE INVENTION

Suitable embodiments for carrying out the present technology will be described below with reference to the drawings. The embodiments described below show an example of a typical embodiment of the present technology and can be combined. Further, the scope of the present technology is not narrowly interpreted thereby. Note that description will be made in the following order.
1. First embodiment
(1) Overview of thermoelectromotive force generating element
(2) Configuration example of thermoelectric conversion element 10
(3) Modified example 1 of thermoelectric conversion element 10
(4) Modified example 2 of thermoelectric conversion element 10
(5) Example of method of producing thermoelectric conversion element 100
(6) Example of method of producing modified example of thermoelectric conversion element 100
(7) Modified example 1 of method of producing thermoelectric conversion element 100
(8) Modified example 2 of method of producing thermoelectric conversion element 100
(9) Modified example 3 of method of producing thermoelectric conversion element 100
2. Second embodiment
3. Third embodiment
(1) Configuration example of thermoelectric conversion element 300
(2) Modified example of thermoelectric conversion element 300
(3) Example of method of producing thermoelectric conversion element 400
(4) Modified example of method of producing thermoelectric conversion element 400
4. Fourth embodiment
(1) Example of method of producing thermoelectric conversion element 600
(2) Example of method of producing thermoelectric conversion element 700

### 1. First Embodiment

### (1) Overview of Thermoelectromotive Force Generating Element

First, an overview of thermoelectromotive force generating element will be described.

In the past, a method itself of forming a thermoelectric conversion material having a high aspect ratio into a PN series connection along a temperature difference in order to obtain thermoelectromotive force from heat that is higher than room temperature, such as factory exhaust heat, with high efficiency has been proposed. However, most of the existing methods use a trench structure in which films are stacked, which makes it difficult to arrange, particularly, one-dimensional pillar structures in series. Here, the trench structure refers to a structure in which two-dimensional thin films are stacked in a direction horizontal to the substrate surface. Further, the pillar structure refers to a structure in which thermoelectric conversion layers are stacked in a columnar shape or a polygonal columnar shape in a direction perpendicular to the substrate surface or light-receiving surface.

Further, with miniaturization, although measure have been taken to ensure strength by using an insulation mold, the thermoelectric efficiency deteriorates due to solid heat diffusion in the mold portion.

An infrared detection element that uses the thermoelectric conversion principle is called a thermopile. In the thermopile, a thermoelectric conversion unit is installed horizontally with respect to the substrate and a cold point electrode unit is installed outward from a hot point electrode unit at the center, which makes an opening narrower. Further, a cavity is provided to suppress heat diffusion from the thermoelectric conversion unit to the substrate side, which makes it very difficult to achieve miniaturization.

The difficulty in miniaturization not only makes it difficult to miniaturize and increase the precision of the element but also increases the thermal time constant that is the heat capacity of the entire element, making the response speed decrease. Further, thermoelectric efficiency deteriorates due to solid heat diffusion by the insulation filling portion, resulting in lower sensitivity. In particular, a core-shell PN series connection structure has not been proposed so far, a thermocouple with a PN series connection having high density has not been obtained, and as a result, the thermoelectromotive force per unit area has been low.

An infrared detection element that thermally detects infrared rays, which is an example of a thermoelectromotive force generating element, has a mechanism in which solid-state heat transfer occurs in a direction horizontal to the substrate. However, this mechanism requires a three-dimensional umbrella structure for increasing the aperture ratio of light and a complicated process for obtaining a three-dimensional structure, such as providing a cavity on the substrate side to prevent heat diffusion, and has a problem that an increase in the volume of the entire element puts a theoretical limit on the response speed and sensitivity.

Meanwhile, in a method of obtaining thermoelectromotive force from the temperature difference between the light-receiving surface and the substrate surface with a structure in which solid-state heat transfer occurs only in a direction perpendicular to the light-receiving surface, the structure is ideal for performing infrared imaging with high sensitivity, high response, and high definition by increasing the efficiency of light and heat use. However, this requires a material control technology that exhibits excellent thermoelectric properties in the film thickness direction, including a low thermal conductivity, and a process technology for forming a thermoelectric conversion element in the film thickness direction.

In this regard, in the present technology, there is provided a thermoelectromotive force generating element in which a thermoelectric conversion layer is formed such that solid-state heat transfer occurs only in a direction perpendicular to the light-receiving surface, a cold point electrode is provided on one end thereof, a hot point electrode is provided on the other end, and these electrodes are connected in PN series. As a result, the present technology makes it possible to provide a thermoelectromotive force generating element capable of generating thermoelectromotive force with high efficiency while maintaining strength even when the element is miniaturized.

### (2) Configuration Example of Thermoelectric Conversion Element 10

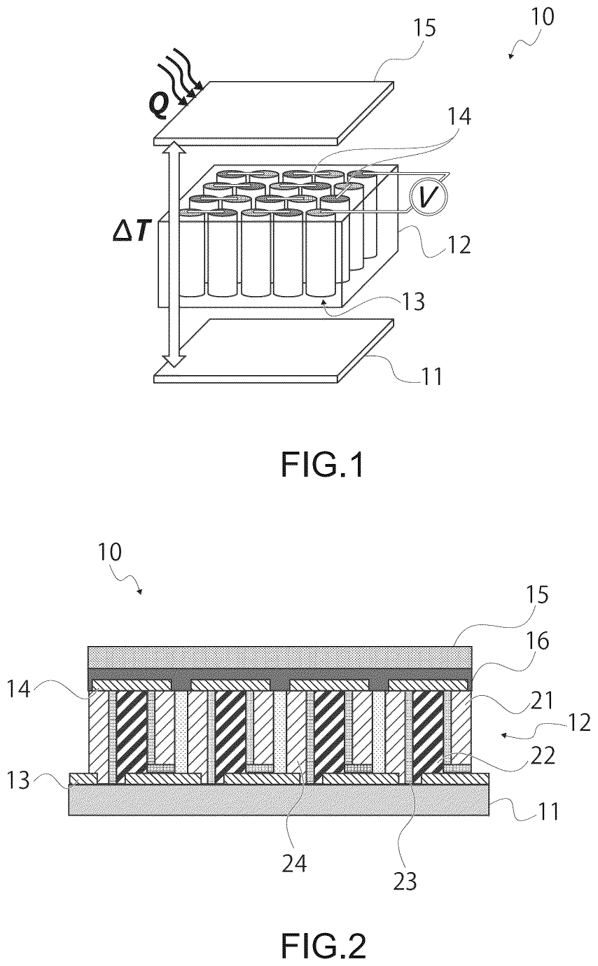

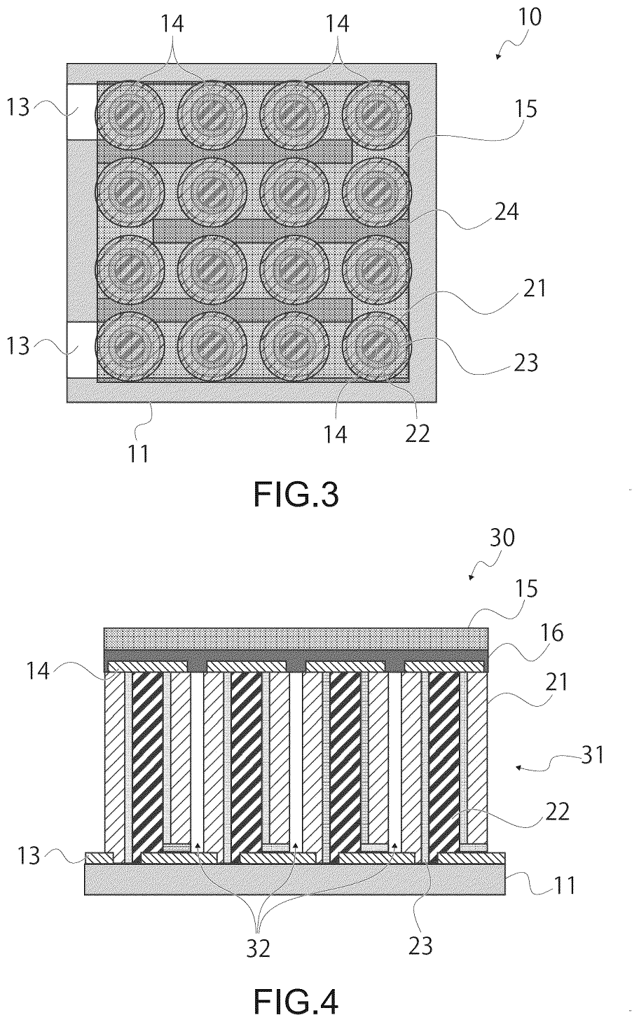

Next, a configuration example of a thermoelectric conversion element 10 that generates thermoelectromotive force corresponding to the amount of heat absorbed from the outside, which is an example of a thermoelectromotive force generating element according to a first embodiment of the present technology, will be described with reference to FIG. 1 to FIG. 3. FIG. 1 is a schematic diagram showing a configuration example of the thermoelectric conversion element 10 according to the first embodiment of the present technology. FIG. 2 is a side cross-sectional view showing a configuration example of the thermoelectric conversion element 10. FIG. 3 is a plan cross-sectional view showing a configuration example of thermoelectric conversion element 10.

As shown in FIG. 1 and FIG. 2, the thermoelectric conversion element 10 includes, as an example, a substrate 11 such as a heat sink, and a thermoelectric conversion layer 12 that is stacked on the substrate 11 and includes a P-type thermoelectric material 21 and an N-type thermoelectric material 22. The P-type thermoelectric material 21 and the N-type thermoelectric material 22 of the thermoelectric conversion layer 12 form a PN series connection.

Further, the thermoelectric conversion element 10 includes a cold point electrode 13 that is a first electrode on a low temperature side connected to the lower part that is one end of the thermoelectric conversion layer 12, a hot point electrode 14 that is a second electrode on a high temperature side connected to the upper part that is the other end of the thermoelectric conversion layer 12, and an absorption portion 15 as an absorption layer that is stacked on the upper part of the hot point electrode 14 and absorbs heat received from the outside, such as infrared rays. Further, in the case where the absorption portion 15 has electrical conductivity, the absorption layer may include, between the thermoelectric conversion layer 12 and the absorption portion 15, an electrical insulation heat transfer body 16 that transfers heat to the hot point electrode 14. Note that in the case where the absorption portion 15 is a film with electrical insulation properties or a heat transfer film, the electrical insulation heat transfer body 16 is unnecessary.

The thermoelectric conversion element 10 is an infrared photodetector for detecting, when heat transfer of a solid heat amount Q occurs vertically from the absorption portion 15 that is a light-receiving surface for absorbing heat due to incident light toward the substrate 11, thermoelectromotive force V caused by a temperature difference ΔT generated between the hot point electrode 14 on the light-receiving surface side and the cold point electrode 13 on the side of the substrate 11.

As shown in FIG. 2, in the thermoelectric conversion layer 12 of the thermoelectric conversion element 10, a plurality of core-shell structure is formed, the periphery of one of the P-type thermoelectric material 21 and the N-type thermoelectric material 22 being covered and surrounded by the other in the respective core-shell structures. Specifically, in the thermoelectric conversion layer 12, a plurality of core-shell pillar structures is arrayed, a columnar N-type thermoelectric material 22 being disposed in the center of a hollow cylindrical P-type thermoelectric material 21 in the core-shell pillar structure. Note that although the thermoelectric conversion layer 12 is described as having a columnar shape in this embodiment for convenience, the shape of the column is not limited to a columnar shape and may be a polygonal columnar shape such as a rectangular shape and a hexagonal columnar shape. Further, in the thermoelectric conversion layer of the core-shell pillar structure, one layer only needs to be an N-type thermoelectric material and the other layer only needs to be a P-type thermoelectric material. The center of the cylindrical shape or rectangular shape may be either an N-type thermoelectric material or a P-type thermoelectric material.

The material forming the thermoelectric conversion layer 12 is not particularly limited as long as it can be used for a semiconductor. For example, any of elements of C, Si, Ge, Sn, P, As, Sb, Bi, and Te, a mixture of any of the above elements, a chalcogenide compound represented by the following general formula (1), a layered compound represented by the composition formula of the general formula (2), or an alloy represented by the composition ratio of the general formula (3) can be suitably used.

$${M}_{n} {Q}_{m} ( 0 < n \leq 2 , 0 < m \leq 3 ) \qquad ( 1 )$$

(In the formula, M represents any of C, Si, P, As, Sb, Te, Bi, Mg, Cu, Ag, Co, Ti, Zr, Hf, V, Nb, Ta, Mo, W, Sc, Mn, Fe, Ni, Cr, Pd, Pt, Re, Ga, Ge, Sn, Pb, Nb, and In, and

Q represents any of C, Si, Ge, Sn, P, As, Sb, Bi, O, S, Se, and Te.)

$${L}_{X} {R}_{Y} {A}_{Z} {B}_{1 - Z} ( 0 < X \leq 1 ) , ( 0 \leq Y \leq 1 ) , ( 0 < Z \leq 1 ) \qquad ( 2 )$$

(In the formula, L or R represents any of Ti, Zr, Hf, V, Nb, Ta, Mo, W, Sc, Mn, Fe, Ni, Cr, Pd, Pt, Re, Cu, Zn, Ga, Ge, Sn, Pb, and In,

A represents any of N, O, P, S, Se, and Te, and

B represents any of N, O, P, S, Se, and Te)

$$XYZ or {X}_{2} Y Z \qquad ( 3 )$$

(In the formula, X, Y, or Z represents any of Fe, Co, Ni, Cu, Zn, Ru, Rh, Pd, Ag, Cd, Ir, Pt, Au, Ti, V, Cr, Mn, Y, Zr, Nb, Hf, Ta, Al, Si, Ga, Ge, As, In, Sn, Sb, Ti, Pd, and Bi.)

By doping the thermoelectric conversion layer 12 with B, P, As, Sb, Al, or Ga to contain it, the thermoelectric physical properties, the n-type, and the p-type can be controlled. There is no particular problem with the doping amount as long as it is an amount suitably used in a semiconductor, and it can be contained in the amount of, for example, 0% to 50% with respect to the entire material of the N-type thermoelectric material or P-type thermoelectric material in the thermoelectric conversion layer 12. Further, in the layered compound represented by the composition formula of the general formula (2), the above B, P, As, Sb, Al, or Ga as an element or a metal oxide, a metal nitride, a metal chloride, a metal oxyhalide, a transition metal chalcogenide, an organic molecule, a conductive polymer, an organic metal, or a carbide can be introduced.

The thermoelectric conversion element 10 includes, between each of the P-type thermoelectric materials 21 and each of the N-type thermoelectric materials 22, an insulation film 23 for insulating the interface between the P-type thermoelectric material 21 and the N-type thermoelectric material 22. Further, the thermoelectric conversion element 10 includes an insulation filling portion 24 for filling the space between core-shell pillar structures, the P-type thermoelectric material 21 and the N-type thermoelectric material 22 being disposed in the respective core-shell pillar structures. The insulation filling portion 24 is formed of a porous material such as a porous insulation material, as an example.

The insulation material forming the insulation film 23, the insulation filling portion 24, and the like is not limited as long as it is a material that ensures electrical and thermal insulation between adjacent layers via the insulation material. For example, an oxide, a nitride, and an organosilicon compound of a Group 14 element, such as SiO₂ and SiN_{X} (0<x<2), or a resin containing any of these compounds can be suitably used.

Note that the arrangement of the P-type thermoelectric material 21 and the N-type thermoelectric material 22 is not limited to the above. A columnar P-type thermoelectric material 21 is disposed in the center and a hollow cylindrical N-type thermoelectric material 22 may be disposed to cover the periphery of the columnar P-type thermoelectric material 21. Further, the aspect ratio (columnar height/diameter of a base circle) of the thermoelectric conversion layer 12 is desirably 10 or more. As a result, it is possible to improve the thermoelectromotive force and sensitivity of the thermoelectric conversion element 10. The upper limit of the aspect ratio of the thermoelectric conversion layer 12 is not particularly limited, and it can be suitably used even when the aspect ratio is, for example, 100, favorably 20.

The hot point electrode 14 electrically connects the upper surfaces of the P-type thermoelectric material 21 and the N-type thermoelectric material 22 in the core-shell pillar structure. The cold point electrode 13 electrically connects the lower part of the N-type thermoelectric material 22 in one core-shell pillar structure and the lower part of the P-type thermoelectric material 21 in the core-shell pillar structure adjacent thereto to each other.

Further, as shown in FIG. 3, in the thermoelectric conversion element 10, a plurality of core-shell pillar structures is arrayed vertically and horizontally in plan view and core-shell pillar structures adjacent to each other in the right and left direction are electrically connected to each other, as an example. Further, in the thermoelectric conversion element 10, parts of core-shell pillar structures adjacent to each other in the up-and-down direction are electrically connected to each other and thus, all the core-shell pillar structures are connected in series.

The present technology provides a thermoelectromotive force generating element such as a thermoelectric conversion element and a thermoelectromotive force infrared detection element in which thermoelectric conversion layers having specific structures and different polarities are electrically and thermally connected between an absorption layer that absorbs infrared rays or the like and a hot point electrode to which heat is transferred therefrom and a cold point electrode opposed to the hot point electrode and a substrate that serves as a heat sink.

The cold point electrode 13 or the hot point electrode 14 may further include, in addition to the electrode portion, an electrode seed layer as a layer for suppressing peeling of the electrode on the side to be connected to the thermoelectric conversion layer 12. The electrode seed layer can also function as a diffusion protection layer that prevents the material forming the electrode portion from diffusing into the P-type thermoelectric material 21, the N-type thermoelectric material 22, and the insulation film 23 of the thermoelectric conversion layer 12. The electrode seed layer is favorably formed in close contact with the side where the electrode portion of the cold point electrode 13 or the hot point electrode 14 is connected to the thermoelectric conversion layer 12. Further, as the material of the electrode seed layer, Cr, W, Ti, Ta, Ni, a nitride of these elements, such as Mo, TaN, and TiN, a compound including a combination of these elements, such as TiW, or the like can be suitably used.

The material forming the electrode portions of the cold point electrode 13 and the hot point electrode 14 is not particularly limited as long as it has conductivity. For example, a metal such as Au, Pt, Cu, Ag, Ni, and Al or a metalloid such as graphene can be suitably used.

By connecting an extraction electrode to any one pair of electrodes, of the cold point electrodes 13, it is possible to output the thermoelectromotive force generated in the thermoelectric conversion element 10 to the outside. The extraction electrode can be designed such that thermoelectromotive force is output from one of the side of the substrate where the thermoelectric conversion element is stacked and the side of the substrate where the thermoelectric conversion element is not stacked.

In the thermoelectric conversion element 10 according to this embodiment, the thermoelectric conversion layer 12 is formed to have a core-shell pillar structure in which the P-type thermoelectric material 21 and the N-type thermoelectric material 22 having different polarities are disposed concentrically and coaxially via the insulation film 23, as an example of the above specific structure. By forming the pillar structure into a core-shell type, it is possible to obtain a plurality of thermocouples per pillar structure and obtain thermocouples connected in PN series with a high degree of integration per unit area.

Further, although it is necessary to cross-link the pillar structures in order to connect adjacent pillar structures with an electrode, the electrode connection in the pillar structure is easily possible. Further, in order to obtain such a core-shell pillar structure, it only needs to form a pillar structure in the center with the N-type thermoelectric material 22 of the core portion first and form a shell pillar structure of the insulation film 23 and the P-type thermoelectric material 21 having a different polarity sequentially in the peripheral edge portion. For this reason, the thermoelectric conversion element 10 is capable of omitting the process of preparing a mold structure in advance and filling it with a material, which is used to form a general fine pillar structure.

In the thermoelectric conversion element 10, the lower end of the P-type thermoelectric material 21 or the N-type thermoelectric material 22 is connected to the cold point electrode 13 and the upper end of the P-type thermoelectric material 21 or the N-type thermoelectric material 22 is connected to the hot point electrode 14, thereby obtaining one thermocouple. Further, the upper ends of the N-type thermoelectric material 22 and the P-type thermoelectric material 21 having different polarities adjacent to each other are connected to each other via the hot point electrode 14 and the adjacent cold point electrode 13 is connected to the lower end, thereby obtaining another thermocouple. Since these thermocouples are connected in PN series, it is possible to obtain thermoelectromotive force corresponding to the number of thermocouples.

Since the thermoelectric conversion layer 12 is formed along a direction perpendicular to the absorption portion 15 that is a light-receiving surface of infrared rays and the surface of the substrate 11 that is a heat sink in the thermoelectric conversion element 10, a high optical aperture ratio is obtained and highly efficient thermoelectric conversion without wasteful solid heat diffusion in the horizontal direction is possible. Further, since a three-dimensional beam structure including a cavity is not necessary, high strength can be maintained even when miniaturized. As a result, a highly efficient thermoelectric conversion element 10 is obtained, and an infrared detection element with high sensitivity, high response speed, and high definition and infrared imaging using the element are possible.

### (3) Modified Example 1 of Thermoelectric Conversion Element 10

Next, a modified example 1 of the thermoelectric conversion element 10 according to this embodiment will be described with reference to FIG. 4. FIG. 4 is a side cross-sectional view showing the modified example 1 of the thermoelectric conversion element 10.

As shown in FIG. 4, a thermoelectric conversion element 30 according to this modified example 1 includes a thermoelectric conversion layer 31 including the P-type thermoelectric material 21 and the N-type thermoelectric material 22, similarly to the thermoelectric conversion element 10. Other configurations of the thermoelectric conversion element 30 are similar to those of the thermoelectric conversion element 10.

In the thermoelectric conversion layer 31, similarly to the thermoelectric conversion layer 12, a plurality of core-shell pillar structures is arrayed, the core-shell pillar structure being formed by the P-type thermoelectric material 21 and the N-type thermoelectric material 22. A gap 32 is formed between core-shell pillar structures in the thermoelectric conversion layer 31.

### (4) Modified Example 2 of Thermoelectric Conversion Element 10

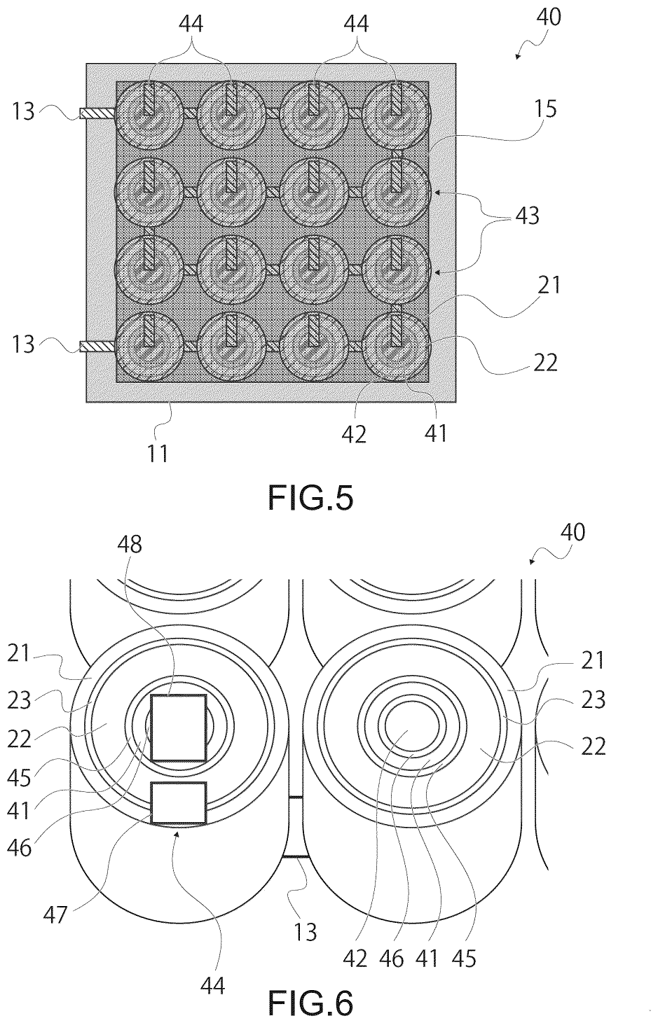

Next, a modified example 2 of the thermoelectric conversion element 10 according to this embodiment will be described with reference to FIG. 5 and FIG. 6. FIG. 5 is a plan cross-sectional view showing the modified example 2 of the thermoelectric conversion element 10. FIG. 6 is an enlarged schematic diagram showing the modified example 2 of the thermoelectric conversion element 10.

As shown in FIG. 5, a thermoelectric conversion element 40 according to this modified example 2 includes a thermoelectric conversion layer 43 that is stacked on the substrate 11 and includes the P-type thermoelectric material 21, the N-type thermoelectric material 22, a P-type thermoelectric material 41, and an N-type thermoelectric material 42, similarly to the thermoelectric conversion element 10.

Further, the thermoelectric conversion element 40 includes the cold point electrode 13 that is a first electrode connected to the lower part of the thermoelectric conversion layer 43, a hot point electrode 44 that is a second electrode connected to the upper part of the thermoelectric conversion layer 43, and the absorption portion 15 that is stacked such that the absorption portion 15 is in contact with the second electrode 44 and absorbs heat received from the outside, such as infrared rays. The other configurations of the thermoelectric conversion element 40 are similar to those of the thermoelectric conversion element 10.

As shown in FIG. 6, in the thermoelectric conversion element 40 according to this modified example 2, the PN series connection of the thermoelectric conversion layer 43 is multilayered. As an example, as the core-shell pillar structure of the thermoelectric conversion element 40, the P-type thermoelectric material 21, the insulation film 23, the N-type thermoelectric material 22, an insulation film 45, the P-type thermoelectric material 41, an insulation film 46, and the N-type thermoelectric material 42 are arrayed in this order from the outside toward the center.

Further, the hot point electrode 44 includes, as an example, an outer-periphery-side hot point electrode 47 that electrically connects the P-type thermoelectric material 21 and the N-type thermoelectric material 22 on the outer periphery side to each other, and an inner-peripheral-side hot point electrode 48 that electrically connects the P-type thermoelectric material 41 and the N-type thermoelectric material 42 on the inner peripheral side to each other. The cold point electrode 13 electrically connects, as an example, the P-type thermoelectric material 21 or the P-type thermoelectric material 41 and the N-type thermoelectric material 22 or the N-type thermoelectric material 42 to each other in adjacent core-shell pillar structures.

Since the thermoelectric conversion layer 12 is formed to have a core-shell pillar structure in the thermoelectric conversion element 10 according to this embodiment, the negative/positive is reversed from the insulation mold structure in which the pillar structure of the thermoelectric conversion layer is left by etching. For this reason, the thermoelectric conversion element 10 has the disadvantage that it is easy to create a large gap between pillar structures and taper is less likely to occur. Note that in the case where the thermoelectric conversion element 10 is tapered, it tends to become an upwardly projecting reversed taper.

Further, the thermoelectric conversion element 10 has excellent thermoelectric efficiency and enables high sensitivity, high response, high thermoelectromotive force, and high definition by arranging a plurality of miniaturized core-shell pillar structures having increased density vertically and connecting them in PN series with the upper and lower electrodes. Further, in the thermoelectric conversion element 10, the hot point electrode 14 can be easily formed, and the process of forming a mold and filling an insulation member is unnecessary.

The thermoelectric conversion element 10 has improved reliability by increasing the yield due to the maintenance of the pillar structure by the porous insulation filling portion 24 formed of a porous material, and the formation of the upper structure can be easily facilitated.

As described above, the thermoelectric conversion element 10 allows it to alternately form thermoelectric materials having different polarities with high density while maintaining strength even when the element is miniaturized, and is capable of generating thermoelectromotive force corresponding to the number of thermocouples connected in PN series with high energy efficiency by eliminating the waste due to solid heat diffusion other than this thermoelectric conversion layer 12. Therefore, in accordance with the thermoelectric conversion element 10, it is possible to generate thermoelectromotive force with high efficiency while maintaining strength even when the element is miniaturized.

Further, in accordance with the thermoelectric conversion element 10, it is possible to keep the noise equivalent power (NEP) low. Here, the noise equivalent power (NEP) refers to the amount of infrared incident light, which is equal to the amount of noise that a detection element or circuit has, i.e., the amount of incident light when the signal-to-noise (S/N) is one. Note that the lower the NEP, the more excellent the performance (sensitivity index).

Note that the NEP is the amount of noise in the element (more precisely, “noise voltage density” at 300 K (room temperature) divided by the sensitivity (sensitivity=output voltage V/amount of infrared light W).

### (5) Example of Method of Producing Thermoelectric Conversion Element 100

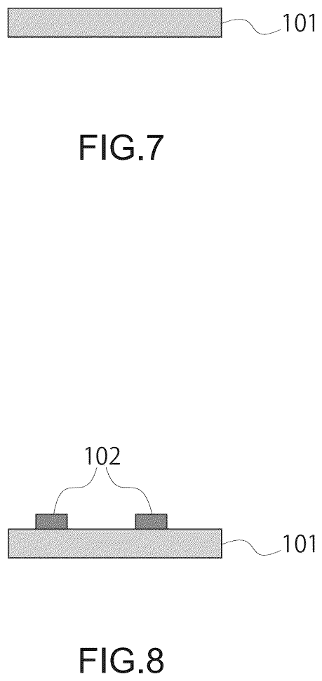

Next, an example of a method of producing a thermoelectric conversion element 100 according to this embodiment will be described with reference to FIG. 7 to FIG. 21. FIG. 7 to FIG. 21 are each a schematic diagram showing an example of a method of producing the thermoelectric conversion element 100. The production method according to this embodiment represents a process of preparing a core-shell pillar structure in a PN series connection and is a method of coating, with an insulating material, a thermoelectric material having a pillar shape formed by etching and depositing thermoelectric materials having different polarities on the insulating material.

As shown in FIG. 7, the method of producing the thermoelectric conversion element 100 disposes a substrate 101 formed of an insulating material, which is a heat sink, in Step 1.

As shown in FIG. 8, in Step 2, a resist pattern 102 for a cold point electrode is formed on the substrate 101.

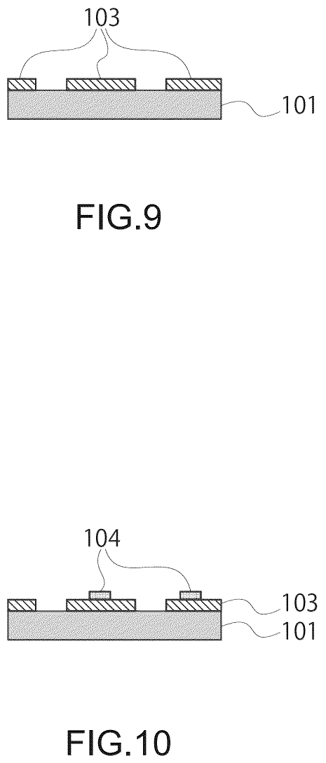

As shown in FIG. 9, in Step 3, a cold point electrode 103 is formed on the substrate 101 on the basis of the resist pattern 102.

As shown in FIG. 10, in Step 4, a cold point electrode insulating film 104 is formed on the cold point electrode 103.

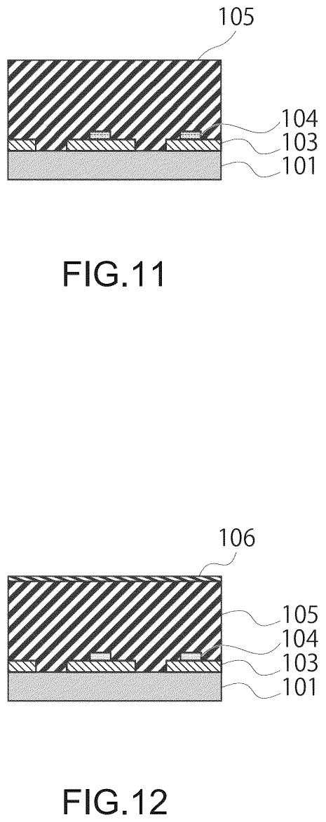

As shown in FIG. 11, in Step 5, a thick film of a P-type thermoelectric material 105 is deposited on the entire surface of the upper surface of the substrate 101.

As shown in FIG. 12, in Step 6, a chromium/silicon dioxide (Cr/SiO₂) film 106 is formed on the thick film of the P-type thermoelectric material 105.

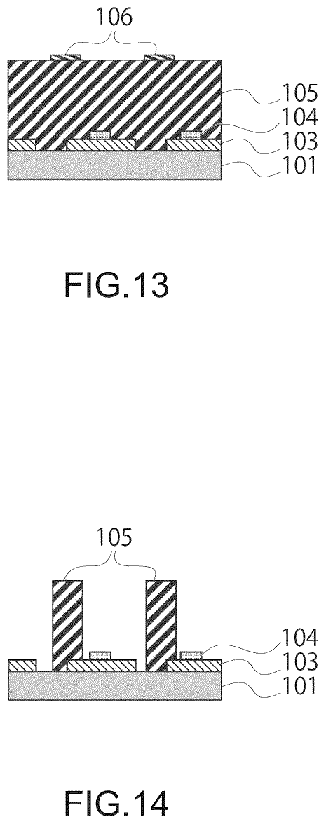

As shown in FIG. 13, in Step 7, an etching mask pattern is formed in the Cr/SiO₂ film 106.

As shown in FIG. 14, in Step 8, the thick film of the P-type thermoelectric material 105 is deeply etched in the stacking direction above the substrate 101.

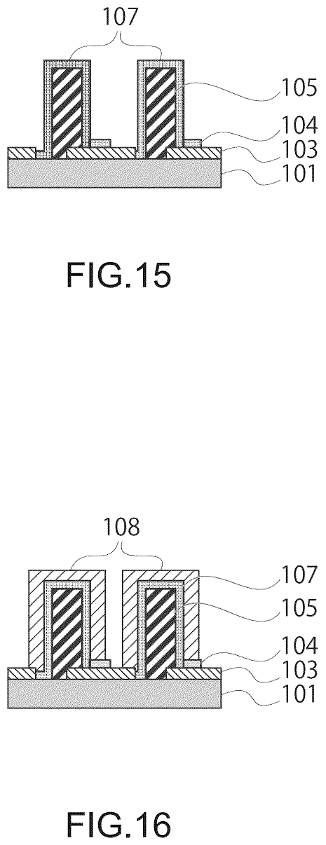

As shown in FIG. 15, in Step 9, an insulation film 107 is deposited on the surface of the P-type thermoelectric material 105 by atomic layer deposition (ALD) or the like.

As shown in FIG. 16, in Step 10, an N-type thermoelectric material 108 with high adhesion to the insulation film 107 is deposited on the surface of the insulation film 107 by chemical vapor deposition (CVD), ALD, plating, or the like.

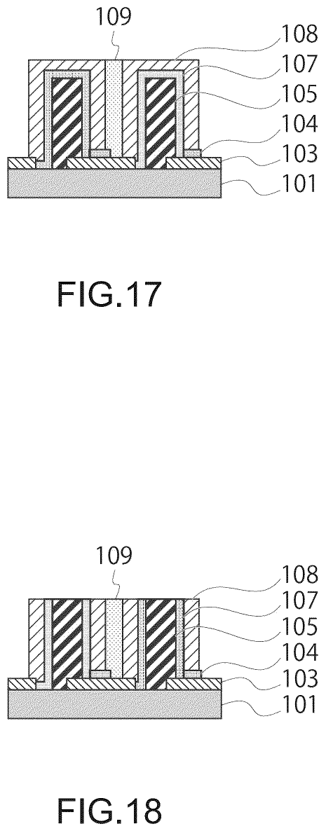

As shown in FIG. 17, in Step 11, the gap between the N-type thermoelectric material 108 and the N-type thermoelectric material 108 is filled with an insulation filling portion 109 using a thermal insulation resist.

As shown in FIG. 18, in Step 12, by soft etching and polishing the upper surface of the N-type thermoelectric material 108, the surfaces of the P-type thermoelectric material 105 and the N-type thermoelectric material 108 are exposed.

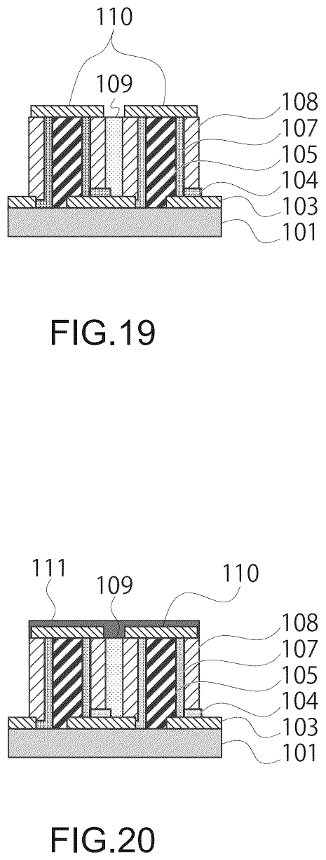

As shown in FIG. 19, in Step 13, a hot point electrode 110 is formed on the upper surfaces of the P-type thermoelectric material 105 and the N-type thermoelectric material 108.

As shown in FIG. 20, in Step 14, an electrical insulation heat transfer body 111 is deposited on the upper surfaces of the P-type thermoelectric material 105, the N-type thermoelectric material 108, and the hot point electrode 110.

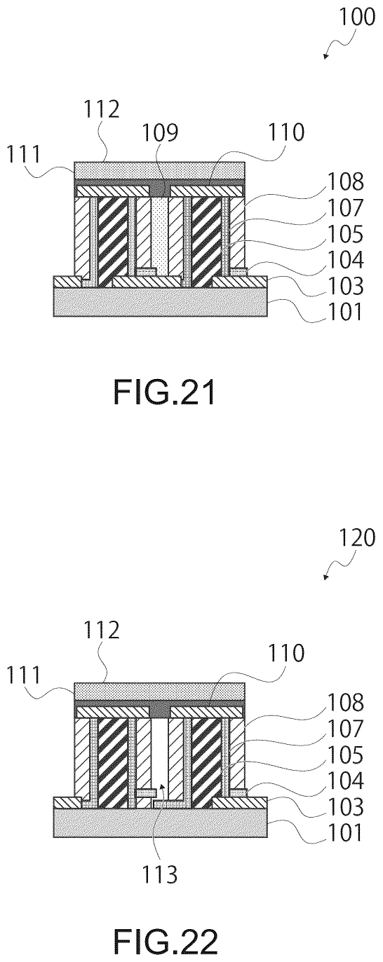

As shown in FIG. 21, in Step 15, an infrared absorption portion 112 deposited on the upper surface of the electrical insulation heat transfer body 111. Note that examples of the material of the absorption portion 112 include metal black including a coarse film formed of metal, and particularly black gold (gold black), which has been used for an infrared detection element in the past. Further, as the material of the absorption portion 112, a film having a surface structure that causes multiple scattering, such as a carbon nanotube forest, can also be used. Such a film is formed on an electrode or heat transfer body by a method such as vapor deposition, transfer, bonding, and vapor phase growth. Through the above Steps, the thermoelectric conversion element 100 is produced.

### (6) Example of Method of Producing Modified Example of Thermoelectric Conversion Element 100

Next, an example of a method of producing a thermoelectric conversion element 120 that is a modified example of the thermoelectric conversion element 100 according to this embodiment will be described with reference to FIG. 7 to FIG. 22. FIG. 22 is a schematic diagram showing an example of a method of producing the thermoelectric conversion element 120.

The method of producing the thermoelectric conversion element 120 is similar to the method of producing the thermoelectric conversion element 100 regarding the above Step 1 to Step 15.

As shown in FIG. 22, in Step 16, the insulation filling portion 109 deposited in the gap between the N-type thermoelectric material 108 and the N-type thermoelectric material 108 is etched by sacrificial layer etching from the side surface or the like. Through the above Steps, the thermoelectric conversion element 120 is produced.

In according with the production method according to this embodiment, it is possible to omit the process of forming a mold and achieve low-cost mass production by significantly reducing the number of steps. Further, since the layers of the P-type thermoelectric material 105/the insulation film 107/the N-type thermoelectric material 108 can be formed in one pillar structure, it is possible to integrate thermocouples at the density approximately twice that of the fine pillar structure. Further, since the hot point electrode 110 is formed only on the surface of the pillar structure and it is unnecessary to cross0-link pillar structures, it is possible to form an electrode simply and without waste heat without filling the insulation mold.

### (7) Modified Example 1 of Method of Producing Thermoelectric Conversion Element 100

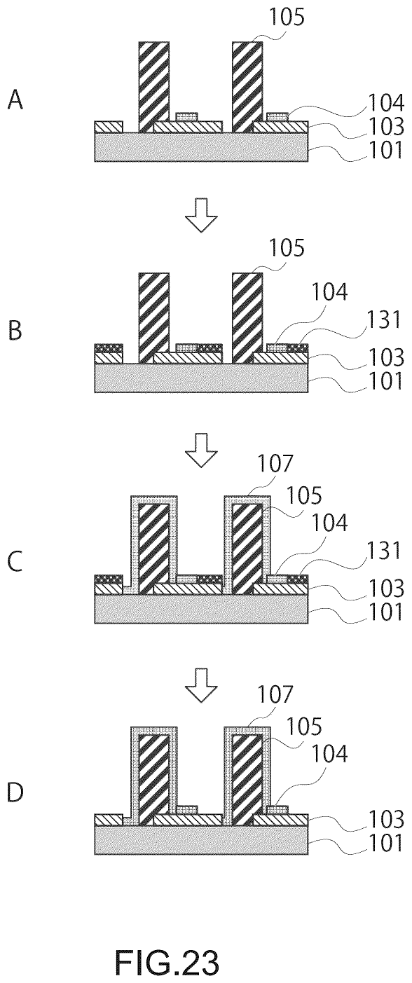

Next, the modified example 1 of the method of producing the thermoelectric conversion element 100 according to this embodiment will be described with reference to FIG. 23. This modified example 1 shows a modified example of the Steps from the above Step 8 to Step 9. Note that the other Steps of this modified example 1 are similar to those in the method of producing the thermoelectric conversion element 100.

Part A of FIG. 23 to Part D of FIG. 23 are each a schematic diagram showing the modified example 1 of the method of producing the thermoelectric conversion element 100. Part A of FIG. 23 shows the same Step as Step 8 shown in FIG. 14. After Step 8, the processing proceeds to Step 21 shown in Part B of FIG. 23.

As shown in Part B of FIG. 23, in Step 21, aniline (C₆H₅NH₂) 131 with high adhesion to an electrode metal is applied.

As shown in Part C of FIG. 23, in Step 22, a trimethylsilane gas that is an insulation film precursor is introduced to cover the entire surface with the insulation film 107.

As shown in Part D of FIG. 23, in Step 23, aniline is removed by lift-off or the like. In this way, similarly to Step 9 shown in FIG. 15, the insulation film 107 is deposited on the surface of the P-type thermoelectric material 105.

After Step 23 shown in Part D of FIG. 23, the processing proceeds to Step 10 shown in FIG. 16 and subsequent Steps. Through the above Steps, the thermoelectric conversion element 100 is produced.

### (8) Modified Example 2 of Method of Producing Thermoelectric Conversion Element 100

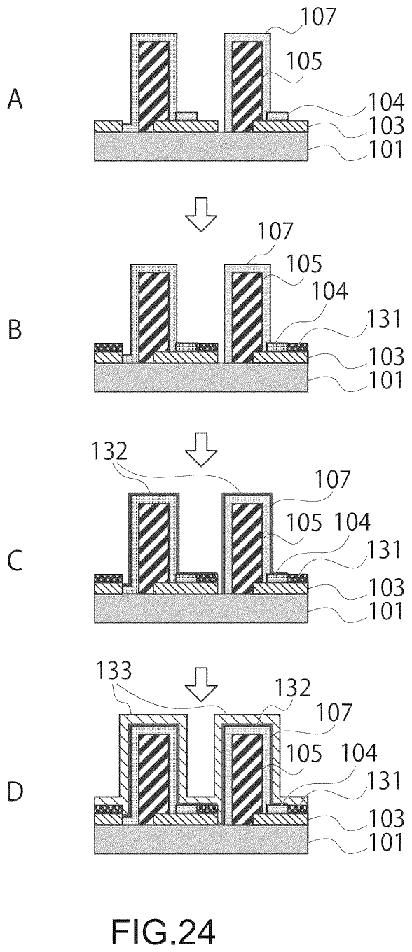

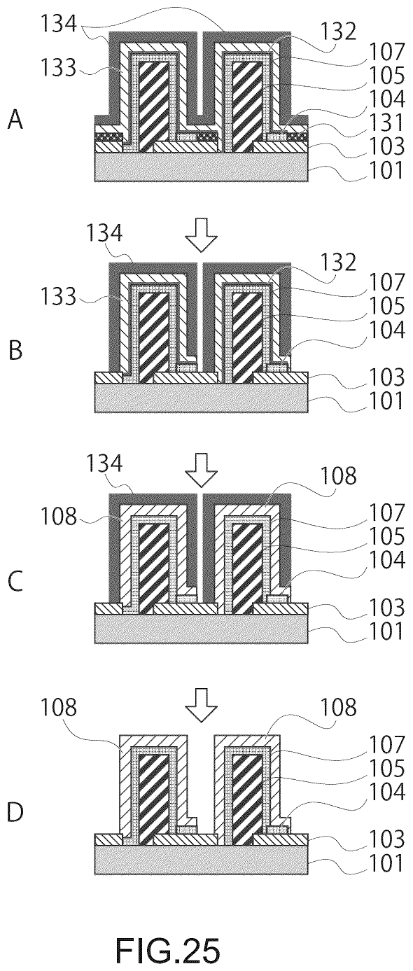

Next, the modified example 2 of the method of producing the thermoelectric conversion element 100 according to this embodiment will be described with reference to FIG. 24 and FIG. 25. This modified example 2 shows a modified example of the Steps from the above Step 9 to Step 10. Note that the other Steps of this modified example 2 are similar to those of the method of producing the thermoelectric conversion element 100.

Part A of FIG. 24 to Part D of FIG. 24 and Part A of FIG. 25 to Part D of FIG. 25 are each a schematic diagram showing the modified example 2 of the method of producing the thermoelectric conversion element 100. Part A of FIG. 24 shows the same Step as Step 9 shown in FIG. 15. After Step 9, the processing proceeds to Step 31 shown in Part B of FIG. 24.

As shown in Part B of FIG. 24, in Step 31, a resist patterning of the aniline (C₆H₅NH₂) 131 is formed.

As shown in Part C of FIG. 24, in Step 32, a close contact layer 132 formed of nickel (Ni) is deposited on the surface of the insulation film 107 by vapor deposition.

As shown in Part D of FIG. 24, in Step 33, an amorphous carbon layer 133 is deposited on the entire surface of the substrate 101 by vapor deposition.

As shown in Part A of FIG. 25, in Step 34, a catalyst layer 134 formed of Ni is deposited on the entire surface of the amorphous carbon layer 133 by vapor deposition.

As shown in Part B of FIG. 25, in Step 35, the aniline 131 is lifted off.

As shown in Part C of FIG. 25, in Step 36, graphene 108 is formed by performing heat treatment on the amorphous carbon layer 133 at 900° C. for 2 minutes.

As shown in Part D of FIG. 25, in Step 37, the catalyst layer 134 formed of a residual catalyst metal is etched. In this way, similarly to Step 10 shown in FIG. 16, the N-type thermoelectric material 108 is deposited on the surface of the insulation film 107.

After Step 37 shown in Part D of FIG. 25, the processing proceeds to Step 11 shown in FIG. 17 and subsequent Steps. Through the above Steps, the thermoelectric conversion element 100 is produced.

In accordance with the production method according to this modified example 2, it is possible to significantly reduce the number of production Steps and reduce costs by patterning, by direct etching, the coated P-type thermoelectric material 105 capable of depositing a thick film and then depositing the insulation film 107 and the N-type thermoelectric material 108 on the surface thereof.

Further, the core portion requires a thick film and is assumed to be deposited in an application process suitable for thick film formation and have a diameter larger than that of the shell portion. Therefore, the P-type thermoelectric material is a nanomaterial that can be used to easily obtain dispersion ink for application as a thermoelectric material with low thermal conductivity and is favorably a layered chalcogenide or two-dimensional stacked body, which is expected to have low thermal conductivity. Meanwhile, the shell portion is deposited to follow the shape of the core portion that has already been formed. For this reason, the N-type thermoelectric material is favorably a metallic thermoelectric material that can easily selectively deposit a thin film because it has excellent chemical reactivity. By selecting these materials, it is possible to easily form a PN series connection structure.

### (9) Modified Example 3 of Method of Producing Thermoelectric Conversion Element 100

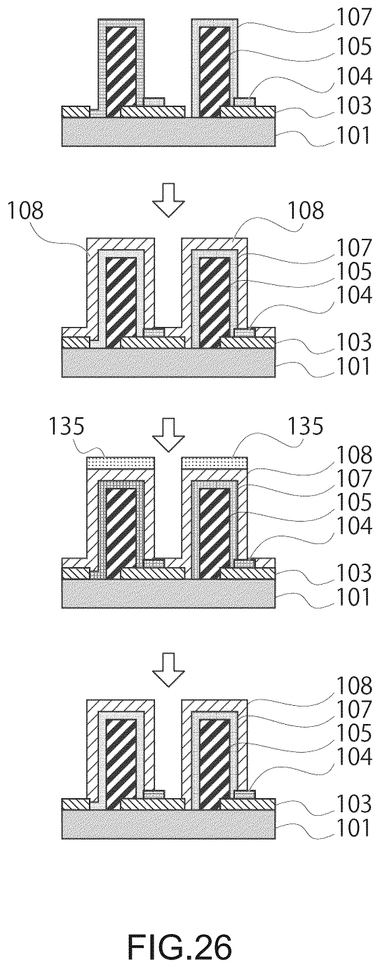

Next, a modified example 3 of the method of producing the thermoelectric conversion element 100 according to this embodiment will be described with reference to FIG. 26. The modified example 3 shows a modified example of the Steps from the above Step 9 to Step 10. Note that the other Steps of this modified example 3 are similar to those of the method of producing the thermoelectric conversion element 100.

Part A of FIG. 26 to Part D of FIG. 26 are each a schematic diagram showing the modified example 3 of the method of producing the thermoelectric conversion element 100. Part A of FIG. 26 shows the same Step as Step 9 shown in FIG. 15. After Step 9, the processing proceeds to Step 41 shown in Part B of FIG. 26.

As shown in Part B of FIG. 26, in Step 41, the N-type thermoelectric material 108 is conformally deposited on the surface of the insulation film 107 by electrochemical deposition.

As shown in Part C of FIG. 26, in Step 42, an etching mask pattern 135 of a chromium/silicon dioxide (Cr/SiO₂) film is formed on the N-type thermoelectric material 108.

As shown in Part D of FIG. 26, in Step 43, anisotropic etching in a direction perpendicular to the surface of the substrate 101 is performed. In this way, similarly to Step 10 shown in FIG. 16, the N-type thermoelectric material 108 is deposited on the surface of the insulation film 107.

After Step 43 shown in Part D of FIG. 26, the processing proceeds to Step 11 shown in FIG. 17 and subsequent Steps. Through the above Steps, the thermoelectric conversion element 100 is produced.

### 2. Second Embodiment

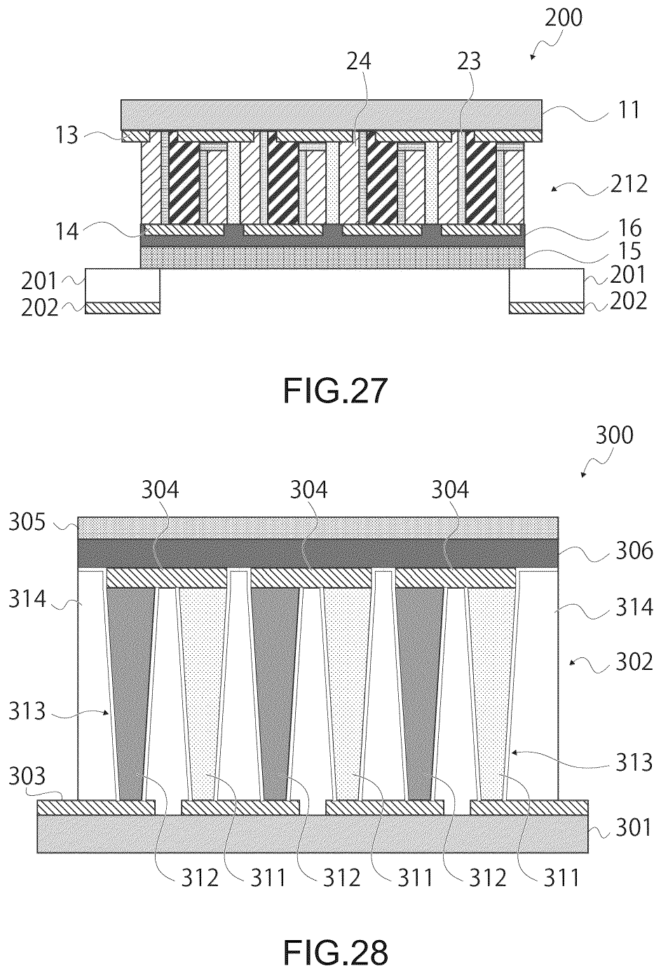

Next, a configuration example of a thermoelectric conversion element 200 according to a second embodiment of the present technology will be described with reference to FIG. 27. FIG. 27 is a side cross-sectional view showing a configuration example of the thermoelectric conversion element 200 according to this embodiment.

The thermoelectric conversion element 200 is different from the thermoelectric conversion element 10 according to the first embodiment in that the entire arrangement from the substrate to the absorption layer is upside down. The other configurations of the thermoelectric conversion element 200 are similar to the configurations of the thermoelectric conversion element 10.

As shown in FIG. 27, the thermoelectric conversion element 200 includes, as an example, the substrate 11 such as a heat sink, and a thermoelectric conversion layer 212 that is stacked on the lower surface of the substrate 11 and includes the P-type thermoelectric material 21 and the N-type thermoelectric material 22. The P-type thermoelectric material 21 and the N-type thermoelectric material 22 of the thermoelectric conversion layer 212 form a PN series connection.

Further, the thermoelectric conversion element 200 includes the cold point electrode 13 that is a first electrode connected to the upper part that is an end of the thermoelectric conversion layer 212, the hot point electrode 14 that is a second electrode connected to the lower part that is the other end of the thermoelectric conversion layer 212, and the absorption portion 15 as an absorption layer that is stacked on the lower part of the hot point electrode 14 and absorbs heat received from the outside, such as infrared rays. Further, in the case where the absorption portion 15 has electrical conductivity, the absorption layer may include, between the absorption portion 15 and the thermoelectric conversion layer 212, the electrical insulation heat transfer body 16 that transfers heat to the hot point electrode 14. Note that in the case where the absorption portion 15 is a film with electrical insulation properties or a heat transfer film, the electrical insulation heat transfer body 16 is unnecessary.

Further, in the thermoelectric conversion layer 212 of the thermoelectric conversion element 200, a plurality of core-shell structures is formed, the periphery of one of the P-type thermoelectric material 21 and the N-type thermoelectric material 22 being covered and surrounded by the other in the respective core-shell structures. Specifically, the thermoelectric conversion layer 212 a plurality of core-shell pillar structures is arrayed, the N-type thermoelectric material 22 having a columnar shape or rectangular shape being disposed in the center of the P-type thermoelectric material 21 having a hollow cylindrical shape or rectangular shape in the respective core-shell pillar structures.

The thermoelectric conversion element 200 includes, between each of the P-type thermoelectric materials 21 and each of the N-type thermoelectric materials 22, the insulation film 23 for insulating the interface between the P-type thermoelectric material 21 and the N-type thermoelectric material 22. Further, the thermoelectric conversion element 200 includes the insulation filling portion 24 for filling the space between core-shell pillar structures, the P-type thermoelectric material 21 and the N-type thermoelectric material 22 being disposed in the respective core-shell pillar structures. The insulation filling portion 24 is formed of a porous material such as a porous insulation material, as an example.

The hot point electrode 14 electrically connects the lower surfaces of the P-type thermoelectric material 21 and the N-type thermoelectric material 22 in the core-shell pillar structure to each other. The cold point electrode 13 electrically connects the upper part of the N-type thermoelectric material 22 in one core-shell pillar structure and the upper part of the P-type thermoelectric material 21 in the core-shell pillar structure adjacent thereto to each other.

Further, the thermoelectric conversion element 200 includes an insulation substrate 201 at both right and left end portions of the lower surface of the absorption portion 15. An infrared reflective layer 202 is provided on the lower surface of the insulation substrate 201. The insulation substrate 201 includes an infrared light introduction hole as a base for a structure in which the hot point electrode 14 and the cold point electrode 13 are upside down. Note that the infrared reflective layer 202 may be a thermal resistance layer.

In accordance with the thermoelectric conversion element 200 according to this embodiment, similarly to the thermoelectric conversion element 10 according to the first embodiment, it is possible to generate thermoelectromotive force with high efficiency while maintaining strength even when the element is miniaturized.

### 3. Third Embodiment

### (1) Configuration Example of Thermoelectric Conversion Element 300

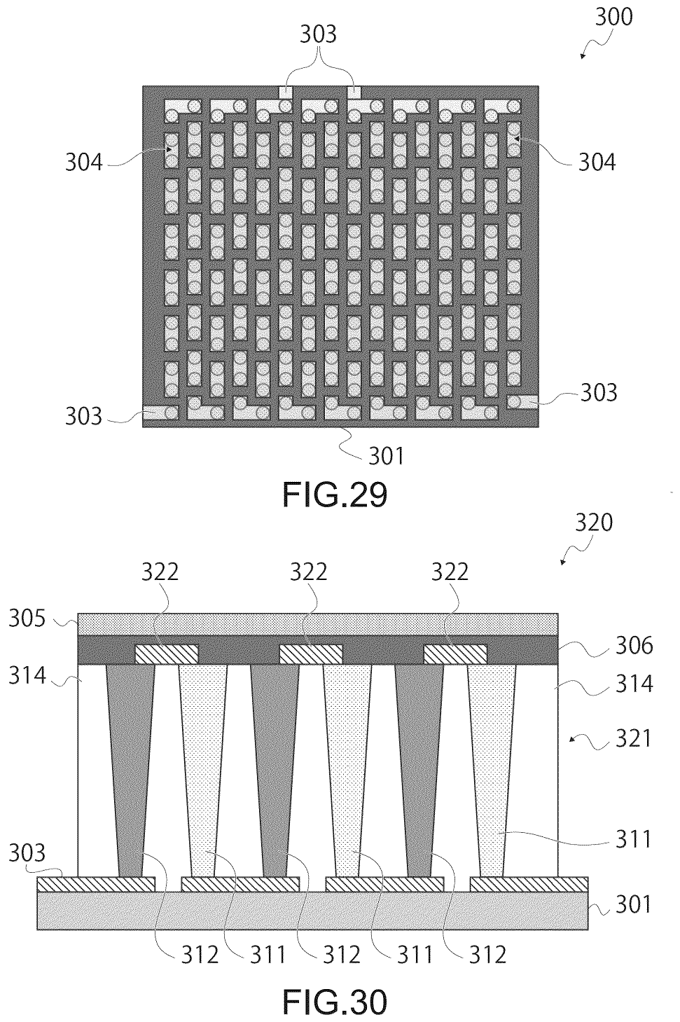

Next, a configuration example of a thermoelectric conversion element 300 according to the third embodiment of the present technology will be described with reference to FIG. 28 and FIG. 29. FIG. 28 is a side cross-sectional view showing a configuration example of the thermoelectric conversion element 300 according to this embodiment. FIG. 29 is a plan cross-sectional view showing a configuration example of the thermoelectric conversion element 300.

The thermoelectric conversion element 300 is different from the thermoelectric conversion element 10 according to the first embodiment in that the thermoelectric conversion layer is formed using an insulation mold. The other configurations of the thermoelectric conversion element 300 are similar to the configurations of the thermoelectric conversion element 10.

As shown in FIG. 28, the thermoelectric conversion element 300 includes, as an example, a substrate 301 such as a heat sink, and a thermoelectric conversion layer 302 that is stacked on the substrate 301 and includes a P-type thermoelectric material 311 and an N-type thermoelectric material 312. The P-type thermoelectric material 311 and the N-type thermoelectric material 312 of the thermoelectric conversion layer 302 form a PN series connection.

Further, the thermoelectric conversion element 300 includes a cold point electrode 303 that is a first electrode connected to the lower part that is an end of the thermoelectric conversion layer 302, a hot point electrode 304 that is a second electrode connected to the upper part that is the other end of the thermoelectric conversion layer 302, and an absorption portion 305 as an absorption layer that is stacked on the upper part of the hot point electrode 304 and absorbs heat received from the outside, such as infrared rays. Further, in the case where the absorption portion 305 has electrical conductivity, the absorption layer may include, between the thermoelectric conversion layer 302 and the absorption portion 305, an electrical insulation heat transfer body 306 that transfers heat to the hot point electrode 304. Note that in the case where the absorption portion 305 is a film with electrical insulation properties or a heat transfer film, the electrical insulation heat transfer body 306 is unnecessary.

The thermoelectric conversion element 300 is an infrared photodetector for detecting, when heat transfer of the solid heat amount Q occurs vertically from the absorption portion 305 that is a light-receiving surface for absorbing heat due to incident light toward the substrate 301, the thermoelectromotive force V caused by the temperature difference ΔT generated between the hot point electrode 304 on the light-receiving surface side and the cold point electrode 303 on the side of the substrate 301.

In the thermoelectric conversion layer 302 of the thermoelectric conversion element 300, an insulation mold 314 is filled with the P-type thermoelectric materials 311 and the N-type thermoelectric materials 312 alternately toward a direction perpendicular to the stacking direction. Each of the P-type thermoelectric material 311 and the N-type thermoelectric material 312 has a pillar structure having a columnar shape or rectangular shape, and is formed in a tapered shape projecting downward from the hot point electrode 304 toward the cold point electrode 303.

The insulation mold 314 is formed of, as an example, a porous material such as a porous insulation material. Further, the thermoelectric conversion layer 302 includes an infrared reflective layer 313 between the insulation mold 314 and the P-type thermoelectric material 311 and between the insulation mold 314 and the N-type thermoelectric material 312. Note that the infrared reflective layer 313 may be a thermal resistance layer.

Since the thermoelectric conversion element 300 includes the infrared reflective layer 313, the temperature gradient can be maintained by reflecting the infrared light transmitted or radiated through the absorption portion 305 by the infrared reflection function. In the case where the infrared reflective layer 313 is a thermal resistance layer, the thermoelectric conversion element 300 is capable of suppressing solid heat diffusion to the insulation mold 314. In this way, the thermoelectric conversion element 300 is capable of achieving higher sensitivity and higher response of the element.

The hot point electrode 304 electrically connects the upper parts of a pair of the P-type thermoelectric material 311 and the N-type thermoelectric material 312 to each other. The cold point electrode 303 electrically connects the lower surfaces having different polarities of a pair of the P-type thermoelectric material 311 and the N-type thermoelectric material 312 adjacent to each other to each other. As a result, the plurality of P-type thermoelectric materials 311 and N-type thermoelectric materials 312 are formed in a PN series connection.

Further, as shown in FIG. 29, in the thermoelectric conversion element 300, a plurality of pillar structures is alternately arrayed vertically and horizontally in plan view, the P-type thermoelectric material 311 and the N-type thermoelectric material 312 being disposed in the respective pillar structures, as an example. As described above, in the thermoelectric conversion element 300, the P-type thermoelectric material 311 and the N-type thermoelectric material 312 having different polarities are arrayed in the thermoelectric conversion layer 302 in a lattice shape, a close-packed shape, or the like and are connected in series by the upper and lower electrodes.

The thermoelectric conversion element 300 according to this embodiment is formed in a pillar structure in which the insulation mold 314 is filled with the P-type thermoelectric material 311 and the N-type thermoelectric material 312 having different polarities alternately and these materials are connected in a PN series connection, as an example of the specific structure of the thermoelectric conversion layer 302. As a result, higher strength can be maintained, and thus, the cross-sectional area of the pillar structure can be reduced. Further, by forming the insulation mold 314 in a porous structure, it is possible to increase the insulation properties of the entire element and the deposition controllability. Further, in the case where a thermal resistance layer is provided on the interface of the insulation mold 314, it is possible to suppress solid heat diffusion to the insulation mold 314.

### (2) Modified Example of Thermoelectric Conversion Element 300

Next, a modified example of the thermoelectric conversion element 300 according to this embodiment will be described with reference to FIG. 30. FIG. 30 is a side cross-sectional view showing a modified example of the thermoelectric conversion element 300.

As shown in FIG. 30, a thermoelectric conversion element 320 according to this modified example includes a thermoelectric conversion layer 321 including the P-type thermoelectric material 311 and the N-type thermoelectric material 312, similarly to the thermoelectric conversion element 300. The other configurations of the thermoelectric conversion element 320 are similar to those of the thermoelectric conversion element 300.

In the thermoelectric conversion layer 321, similarly to the thermoelectric conversion layer 302, the insulation mold 314 is filled with the P-type thermoelectric materials 311 and the N-type thermoelectric materials 312 alternately toward a direction perpendicular to the stacking direction. Each of the P-type thermoelectric material 311 and the N-type thermoelectric material 312 has a pillar structure having a columnar shape or rectangular shape and is formed in a tapered shape projecting downward from a hot point electrode 322 toward the cold point electrode 303.

Since the thermoelectric conversion layer 321 has an insulation mold structure that does not require the infrared reflective layer 313 formed of a metal, the infrared reflective layer 313 is not provided between the insulation mold 314 and the P-type thermoelectric material 311 and between the insulation mold 314 and the N-type thermoelectric material 312.

In the case where the infrared reflective layer 313 is unnecessary or an infrared absorber using a dielectric or the like other than metal is used, short circuit between the hot point electrodes 304 does not become a problem. As a result, since the heat capacity corresponding to the infrared reflective layer 313 formed of a metal can be reduced, it is possible to achieve higher response and higher sensitivity and reduce the costs.

The hot point electrode 322 electrically connects the upper surfaces of a pair of the P-type thermoelectric material 311 and the N-type thermoelectric material 312 to each other. The cold point electrode 303 electrically connects the lower surfaces having different polarities of a pair of the P-type thermoelectric material 311 and the N-type thermoelectric material 312 adjacent to each other to each other. In this way, the plurality of P-type thermoelectric materials 311 and N-type thermoelectric materials 312 is formed in a PN series connection.

In the thermoelectric conversion element 300 according to this embodiment, since the thermoelectric conversion layer 302 is formed in an insulation mold structure, it is necessary to dig into a long thin hole by anisotropic etching or the like when forming the insulation mold 314, the diameter of the excavation surface on the side of the hot point electrode 304 tends to become wider, the diameter of the interface of the substrate 301 on the side of the cold point electrode 303 becomes narrower, and thus, a structure projecting downward is obtained. Therefore, the pillar structure including the P-type thermoelectric material 311 and the N-type thermoelectric material 312 deposited in the insulation mold 314 projects downward.

Then, the thermoelectric conversion element 300 is a thermoelectric conversion element in which one end of the thermocouple of the P-type thermoelectric material 311 and the N-type thermoelectric material 312 supported on the insulation mold 314 is connected to the substrate 301 as a heat sink and the cold point electrode 303 and the other end is connected to the electrical insulation heat transfer body 306 and the hot point electrode 304. As a result, the thermoelectric conversion element 300 is capable of efficiently creating a temperature difference between the side of the electrical insulation heat transfer body 306 and the side of the substrate 301, and it is possible to maintain strength even when miniaturized and generate an electromotive force corresponding to the number of thermocouples in a PN series connection.

In accordance with the thermoelectric conversion element 300 according to this embodiment, similarly to the thermoelectric conversion element 10 according to the first embodiment, it is possible to generate thermoelectromotive force with high efficiency while maintaining strength even when the element is miniaturized. Further, the thermoelectric conversion element 300 has excellent mechanical strength and is capable of achieving high thermoelectric efficiency by arranging pillar structures vertically in the porous insulation mold 314 and connecting them in PN series with the upper and lower electrodes, the P-type thermoelectric material 311 and the N-type thermoelectric material 312 being disposed in the respective pillar structures.

In accordance with the thermoelectric conversion element 300, the heat on the side of the electrical insulation heat transfer body 306 is capable of generating heat carriers in the thermoelectric conversion layer 302 having a large cross-sectional area via the electrodes, and highly efficient thermoelectric conversion can be achieved. The strength on the side of the substrate 301 as a heat sink can be maintained by being supported on the insulation mold 314. Then, using a taper that occurs during the process of forming a mold structure makes it possible to achieve further miniaturization.

Further, by introducing an interface layer between the insulation mold 314 and the P-type thermoelectric material 311 and between the insulation mold 314 and the N-type thermoelectric material 312, it is possible to suppress heat diffusion loss due to radiation or solid-state heat transfer to the insulation mold 314. By using the porous insulation mold 314, it is possible to suppress the heat diffusion loss and facilitate the process of forming a mold structure.

### (3) Example of Method of Producing Thermoelectric Conversion Element 400

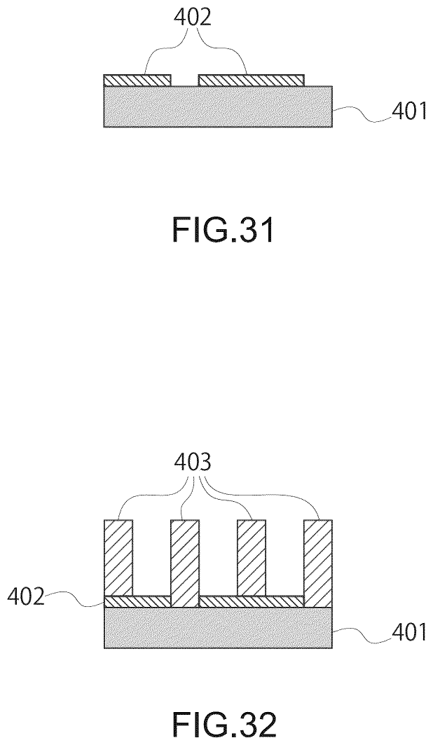

Next, an example of a method of producing a thermoelectric conversion element 400 according to this embodiment will be described with reference to FIG. 31 to FIG. 40. FIG. 31 to FIG. 40 are each a schematic diagram showing an example of the method of producing the thermoelectric conversion element 400. The production method according to this embodiment is a method of filling an insulation mold with thermoelectric materials having different polarities in a stepwise manner using a plurality of types of resists. Further, by adopting a negative resist having low transparency for an insulation mold as a method of suppressing film sagging during deposition of a thermoelectric material, it is possible to prevent short circuit between a thermoelectric conversion layer and a hot point electrode by providing a reverse tapered shape.

In the method of producing the thermoelectric conversion element 400, as shown in FIG. 31, in Step 101, a substrate 401 formed of an insulating material as a heat sink is disposed and a resist pattern of a cold point electrode 402 is formed on the substrate 401.

As shown in FIG. 32, in Step 102, an insulation mold 403 is formed on the substrate 401 and the cold point electrode 402 by thick film resist patterning.

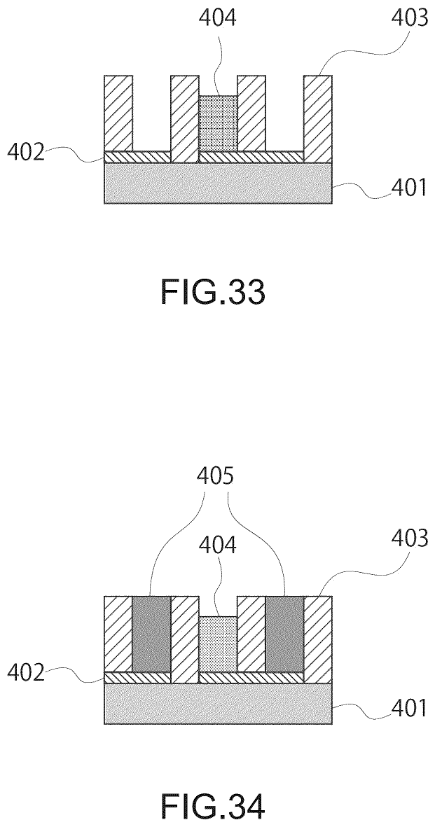

As shown in FIG. 33, in Step 103, the deposition portion of a P-type thermoelectric material of the insulation mold 403 is masked by thin film resist patterning 404.

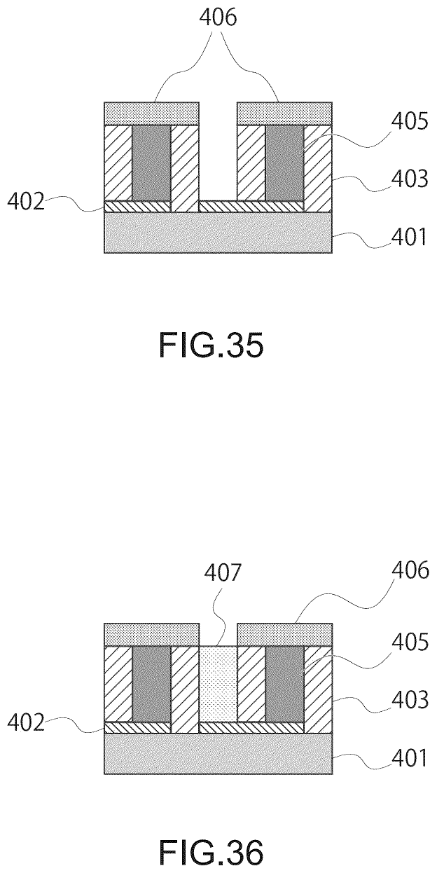

As shown in FIG. 34, in Step 104, an N-type thermoelectric material 405 is deposited by electrodeposition on the cold point electrode 402 on both sides of the deposition portion of a P-type thermoelectric material of the insulation mold 403. As shown in FIG. 35, in Step 105, the surface of the N-type thermoelectric material 405 of the insulation mold 403 is masked by thin film resist patterning 406.

As shown in FIG. 36, in Step 106, a P-type thermoelectric material 407 is deposited by electrodeposition on the portion of the cold point electrode 402 masked by the thin film resist patterning 404.

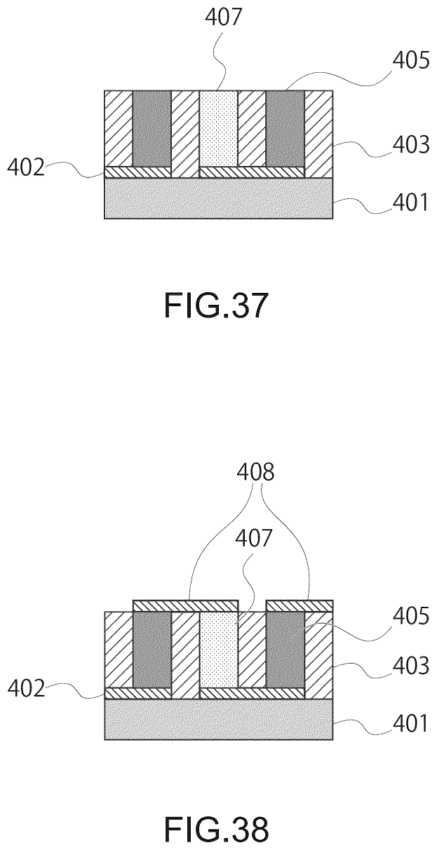

As shown in FIG. 37, in Step 107, by resist etching and polishing the upper surface of the insulation mold 403 in which the N-type thermoelectric material 405 and the P-type thermoelectric material 407 are deposited, the surfaces of the P-type thermoelectric material 407 and the N-type thermoelectric material 405 are exposed.

As shown in FIG. 38, in Step 108, a hot point electrode 408 is patterned on the upper surfaces of a pair of the P-type thermoelectric material 407 and the N-type thermoelectric material 405.

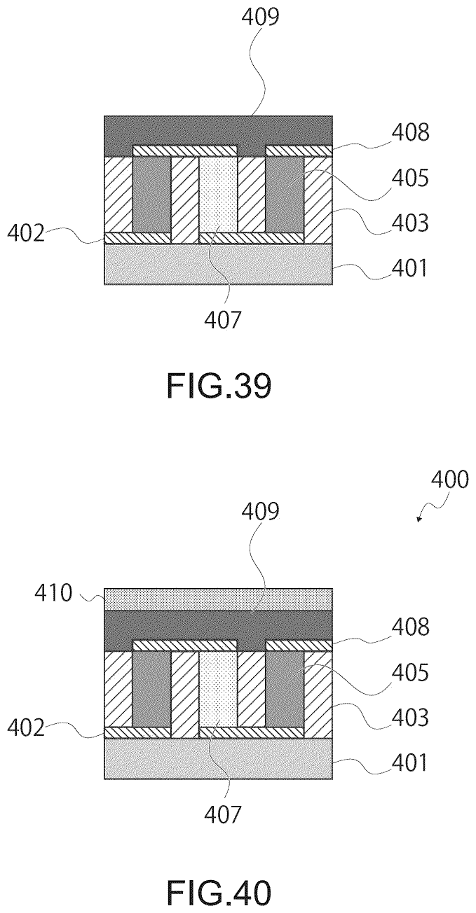

As shown in FIG. 39, in Step 109, an electrical insulation heat transfer body 409 is deposited on the upper surfaces of the P-type thermoelectric material 407, the N-type thermoelectric material 405, and the hot point electrode 408.

As shown in FIG. 40, in Step 110, an infrared absorption portion 410 is deposited on the upper surface of the electrical insulation heat transfer body 409. Through the above Steps, the thermoelectric conversion element 400 is produced.

### (4) Modified Example of Method of Producing Thermoelectric Conversion Element 400

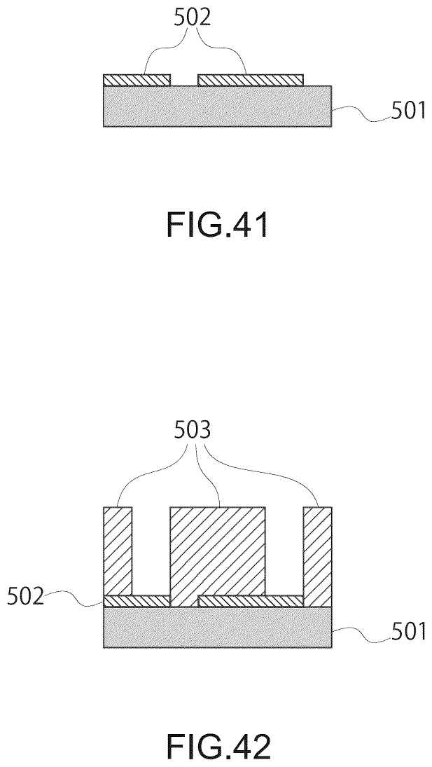

Next, a modified example of the method of producing the thermoelectric conversion element 400 according to this embodiment will be described with reference to FIG. 41 to FIG. 49. FIG. 41 to FIG. 49 are each a schematic diagram showing the method of producing the thermoelectric conversion element 400. The production method according to the modified example is a method of patterning the same type of resist twice by completing the process in a yellow room to deposit a P-type thermoelectric material and an N-type thermoelectric material in a stepwise manner. Note that in order to prevent the risk of etching variation when patterning a thick film resist twice, a thermoelectric material having higher electrical conductivity is used.

In the production method according to this modified example, as shown in FIG. 41, in Step 111, a substrate 501 formed of an insulating material as a heat sink is disposed and a resist pattern of a cold point electrode 502 is formed on the substrate 501.

As shown in FIG. 42, in Step 112, an insulation mold 503 is formed on the substrate 501 and the cold point electrode 502 by primary patterning of a thick film resist.

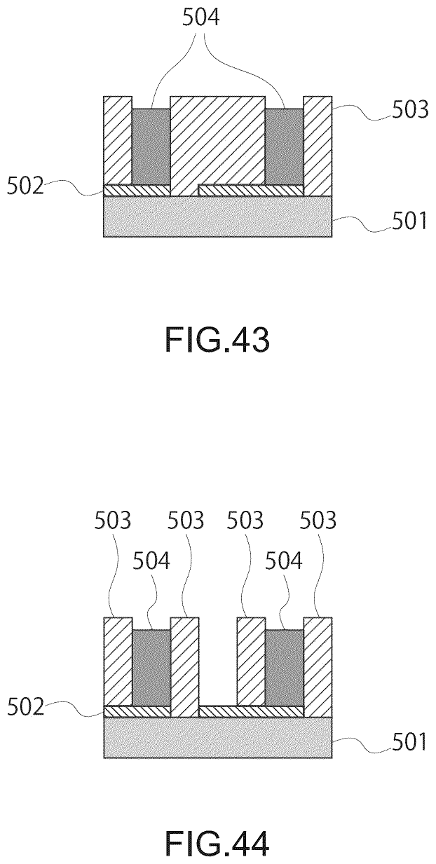

As shown in FIG. 43, in Step 113, an N-type thermoelectric material 504 is deposited on the cold point electrode 502 of the insulation mold 503 by electrodeposition.

As shown in FIG. 44, in Step 114, secondary patterning of a thick film resist is performed between the N-type thermoelectric material 504 of the insulation mold 503 and the N-type thermoelectric material 504.

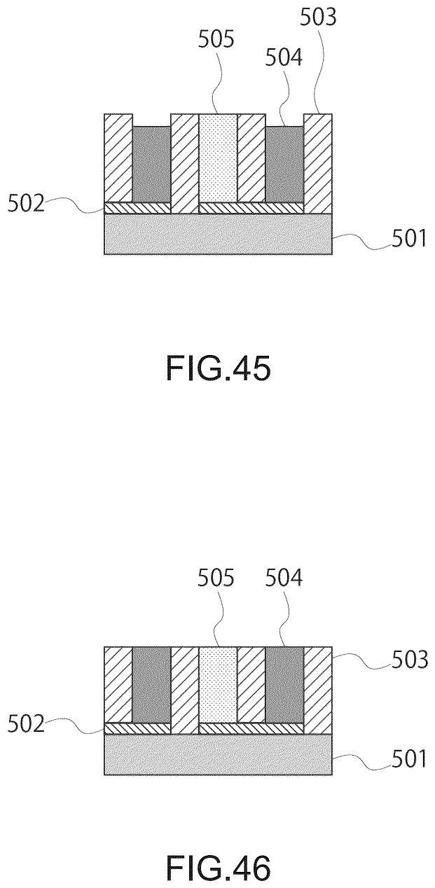

As shown in FIG. 45, in Step 115, a P-type thermoelectric material 505 is deposited by electrodeposition on the portion of the cold point electrode 502 on which the secondary patterning of a thick film resist has been performed.

As shown in FIG. 46, in Step 116, by resist etching and polishing the upper surface of the insulation mold 503 in which the N-type thermoelectric material 504 and the P-type thermoelectric material 505 are deposited, the surfaces of the P-type thermoelectric material 505 and the N-type thermoelectric material 504 are exposed.

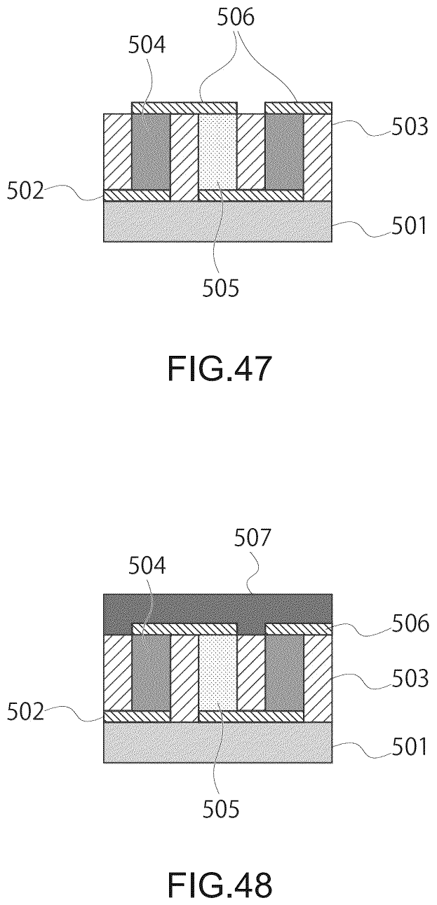

As shown in FIG. 47, in Step 117, a hot point electrode 506 is patterned on the upper surface of a pair of the P-type thermoelectric material 505 and the N-type thermoelectric material 504.

As shown in FIG. 48, in Step 118, an electrical insulation heat transfer body 507 is deposited on the upper surfaces of the P-type thermoelectric material 505, the N-type thermoelectric material 504, and the hot point electrode 506.

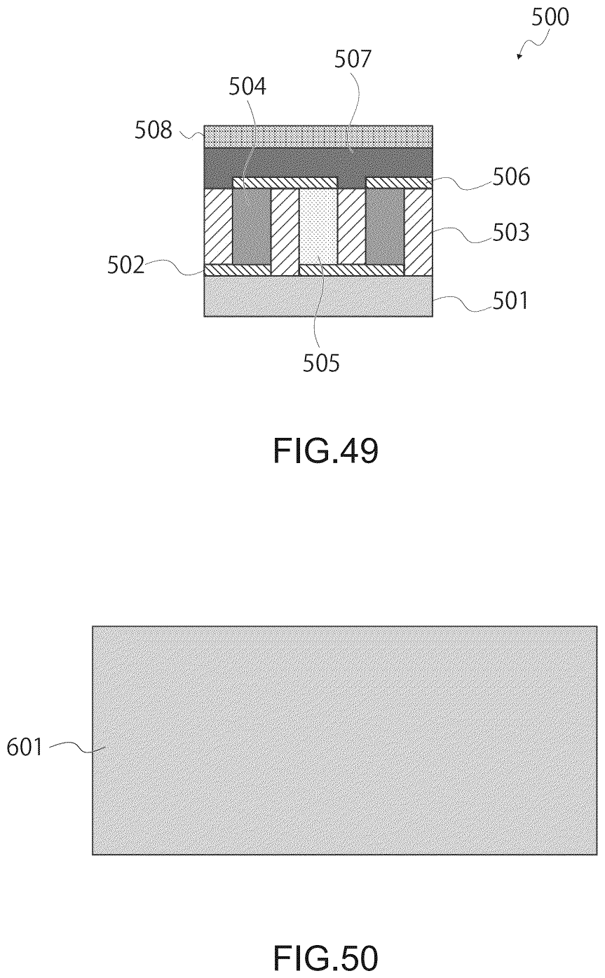

As shown in FIG. 49, in Step 119, an infrared absorption portion 508 is deposited on the upper surface of the electrical insulation heat transfer body 507. Through the above Steps, the thermoelectric conversion element 500 is produced.

### 4. Fourth Embodiment

### (1) Example of Method of Producing Thermoelectric Conversion Element 600

Next, an example of a method of producing a thermoelectric conversion element 600 according to this embodiment will be described with reference to FIGS. 50 to 76. FIGS. 50 to 76 are each a schematic diagram showing an example of the method of producing the thermoelectric conversion element 600. The production method according to this embodiment is a method of forming the center of a core-shell structure relating to a thermoelectric conversion layer in the initial stage of production.

In the method of producing the thermoelectric conversion element 600 according to this embodiment, in Step 201, as shown in FIG. 50, a core layer substrate 601 is disposed. The core layer substrate 601 serves as a core layer that is the center of a core-shell structure relating to a thermoelectric conversion layer. As the material forming the core layer substrate 601, either the P-type thermoelectric material or the N-type thermoelectric material disclosed in the present specification may be selected. Further, a P-type thermoelectric material or an N-type thermoelectric material may be obtained by performing doping treatment with a material after forming the core layer. The doping treatment method performed after forming the core layer is not particularly limited, but can be performed by ion implantation, solution reaction, gas phase intercalation, liquid phase intercalation, or the like. Further, the thickness of the core layer substrate 601 is not particularly limited, and the core layer substrate 601 can be suitably produced to have a thickness of, for example, 1 to 100 μm.

Further, the core layer substrate 601 may have a two-layer structure obtained by depositing the above-mentioned material forming the core layer substrate 601 on a silicon substrate, a quartz substrate, a sapphire substrate, or the like by an arbitrary method such as atomic layer deposition (ALD) and chemical vapor deposition (CVD method).

After a photosensitive resist for photolithography is applied and deposited on the surface of the core layer substrate 601 by spin coating, prebaking treatment for removing the solvent from the applied resist film is performed. Note that ozone treatment or surface treatment using hexamethyldisilazane (HMDS) may be performed on the core layer substrate 601 before depositing a resist film.

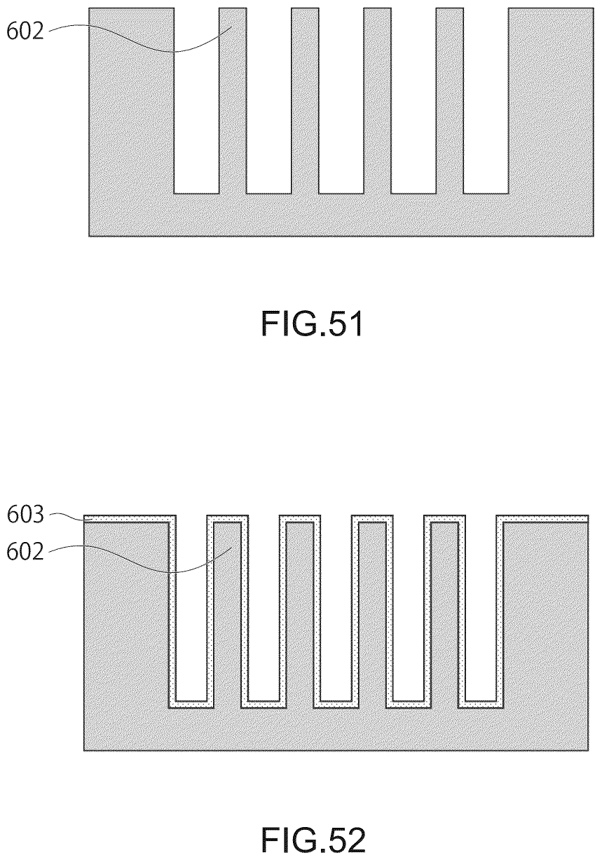

As shown in FIG. 51, in Step 202, after exposing the resist pattern of a core layer 602 that is the center of the core-shell structure relating to the thermoelectric conversion layer by a photolithography exposure device, anisotropic etching using dry etching or wet etching is performed to form the core layer 602. The above core layer may be formed not only by using a resist as a mask but also by using a hard mask formed of SiO₂, SiN_{X} (0<x<2), a metal, or the like. The material relating to the mask is removed by anisotropic etching treatment such as ashing treatment and dry etching. Hereinafter, in the present specification, the above-mentioned method of forming a target object by depositing a photosensitive resist for photolithography and performing anisotropic etching will be referred to as a “photolithography method”. Further, examples of the anisotropic etching method performed in the present specification include, but not limited to, inductively coupled plasma reactive ion etching (ICP-RIE), dry etching such as atomic layer etching, and wet etching. Note that the aspect ratio (height/pillar diameter) of the core layer 602 can be suitably selected from the range of, for example, 10 to 100, and the diameter of the core layer 602 can be suitably selected from the range of 100 to 5000 nm. Further, as the shape of the core layer 602, any of a columnar shape, a rectangular shape, and a polygonal columnar shape can be suitably used, similarly to the other embodiments.

As shown in FIG. 52, in Step 203, an insulation layer film 603 is deposited so as to follow the surface of the core layer 602. As the method of depositing the insulation layer film 603, atomic layer deposition (ALD method), chemical vapor deposition method (CVD method), or the like can be appropriately selected. The film thickness of the insulation layer film 603 can be suitably selected in the range of, for example, 50 to 500 nm. As the material forming the insulation layer film 603, the insulation material described in the present specification can be appropriately selected.

As shown in FIG. 53, in Step 204, a shell layer 604 is deposited so as to follow the surface of the core layer 61 on which the insulation layer film 603 is formed. As the method of depositing the shell layer 604, atomic layer deposition (ALD method), chemical vapor deposition method (CVD method), or an ion sputtering method can be appropriately selected. The film thickness of the shell layer 604 can be suitably selected from the range of, for example, 50 to 500 nm. Further, as the material forming the shell layer 604, a thermoelectric material of a type different from that of the core layer substrate 602, of the P-type thermoelectric material or the N-type thermoelectric material described in the present specification, can be appropriately selected. This material may be used and deposited, but a P-type thermoelectric material or an N-type thermoelectric material may be obtained by performing doping treatment after deposition. The doping treatment method performed after forming the shell layer 604 is not particularly limited, but can be performed by ion implantation, solution reaction, gas phase intercalation, liquid phase intercalation, or the like.

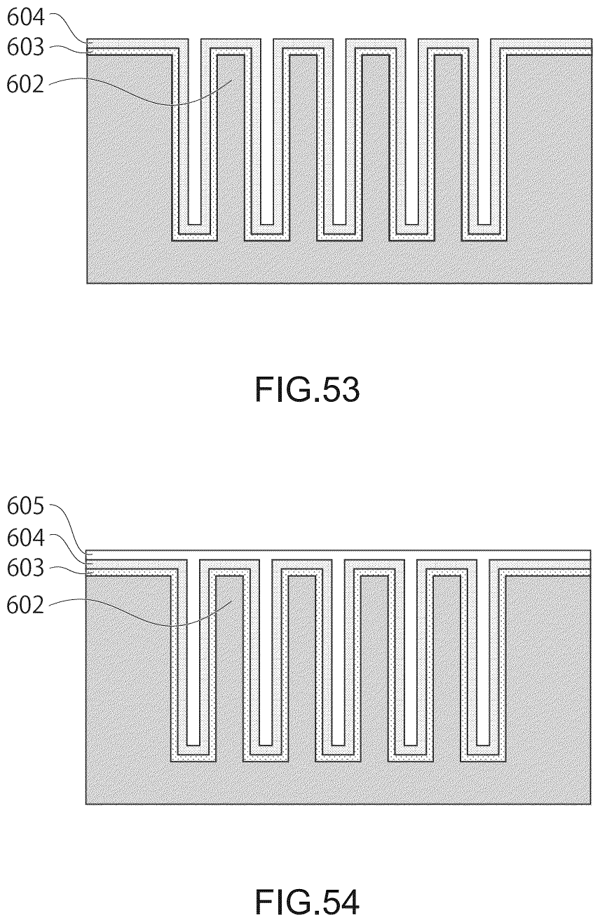

As shown in FIG. 54, in Step 205, the gap between the shell layer 63 and the shell layer 604 is filled with an insulation filling portion 605 using a thermal insulation resist. As the method of depositing the insulation filling portion 605, atomic layer deposition (ALD method), chemical vapor deposition method (CVD method), an application deposition method, or the like can be appropriately selected. As the material forming the insulation filling portion 605, the insulation material described in the present specification can be appropriately selected.

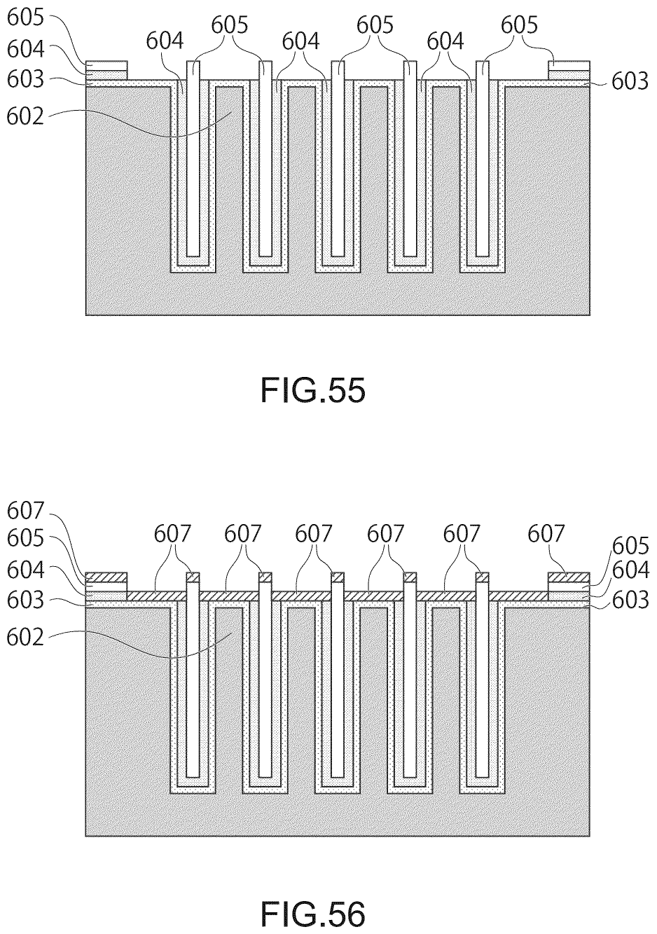

As shown in FIG. 55, in Step 206, the pattern of a cold point electrode 606 is formed by the photolithography method described in the present specification.

As shown in FIG. 56, in Step 207, an electrode seed layer 607 is deposited by a method such as atomic layer deposition (ALD method), chemical vapor deposition method (CVD method), and an ion sputtering method. The film thickness of the electrode seed layer 607 can be suitably selected from the range of, for example, 1 to 100 nm. As the material forming the electrode seed layer 607, the material forming the electrode seed layer described in the present specification can be appropriately selected. The deposition of the electrode seed layer 607 is not an essential Step and can also be omitted as appropriate.

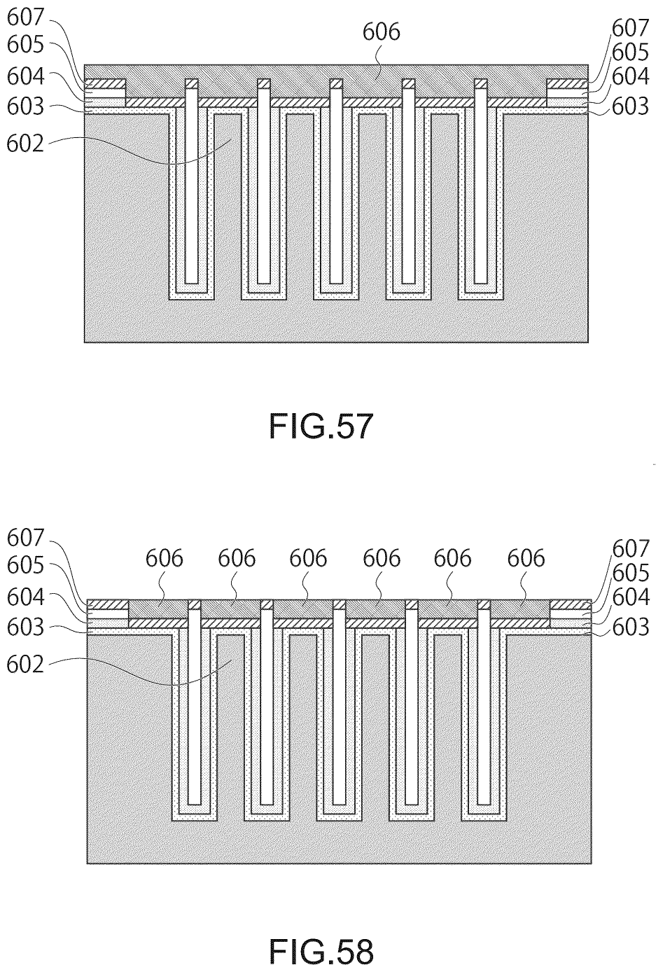

As shown in FIG. 57, in Step 208, the cold point electrode 606 is deposited by a method such as a plating method. As the material forming the cold point electrode 606, the material forming the electrode described in the present specification can be appropriately selected.

As shown in FIG. 58, in Step 209, the cold point electrode 606 is formed by surface flattening by chemical mechanical polishing (CMP).

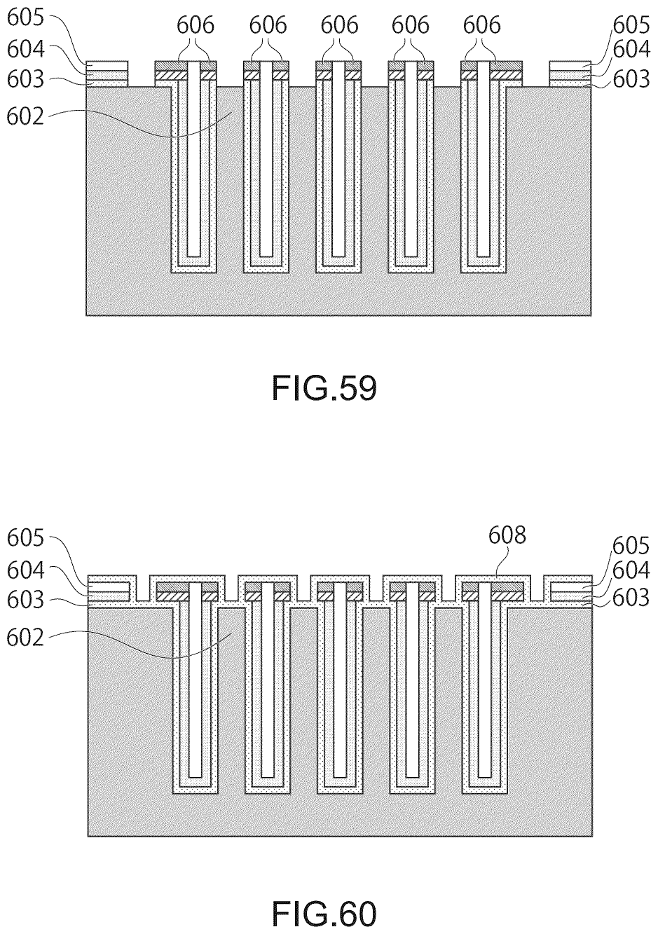

As shown in FIG. 59, in Step 210, the pattern of a cold point electrode insulating film 608 is formed by the photolithography described in the present specification.

As shown in FIG. 60, in Step 211, the cold point electrode insulating film 608 is deposited by a method such as atomic layer deposition (ALD method), chemical vapor deposition method (CVD method), and an ion sputtering method. The film thickness of the cold point electrode insulating film 608 can be suitably selected from the range of, for example, 10 to 100 nm. As the material forming the cold point electrode insulating film 608, the insulation material described in the present specification can be appropriately selected.

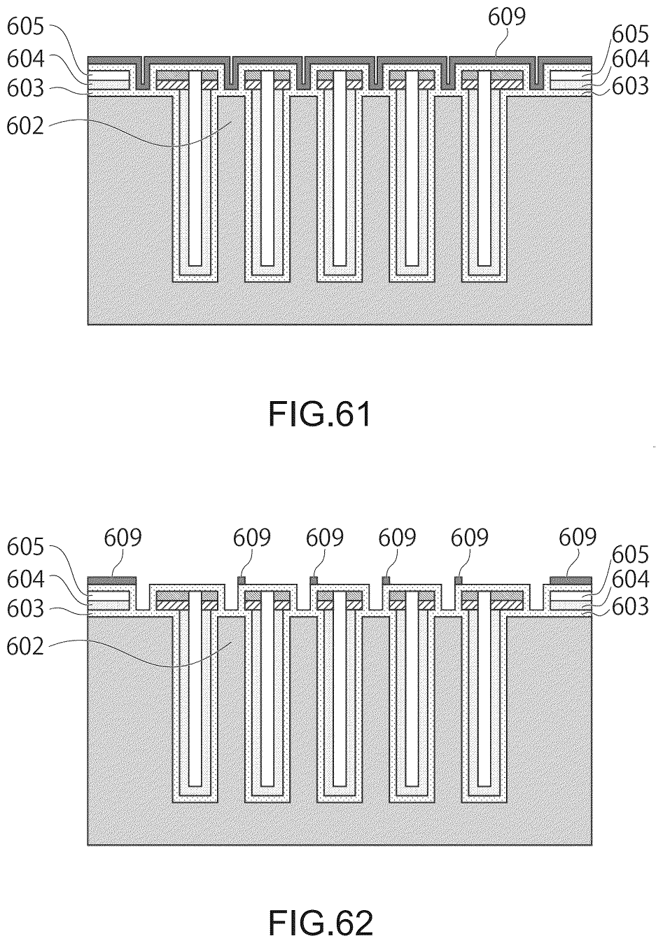

As shown in FIG. 61, in Step 212, an insulation mold 609 is deposited by a method such as atomic layer deposition (ALD method), chemical vapor deposition method (CVD method), and an ion sputtering method. The film thickness of the insulation mold 609 can be suitably selected from the range of, for example, 10 to 100 nm. As the material forming the insulation mold 609, a material different from the material used for the cold point electrode insulating film 608, of the insulation materials described in the present specification, can be appropriately selected.

As shown in FIG. 62, in Step 213, the insulation mold 609 is formed by the photolithography described in the present specification.

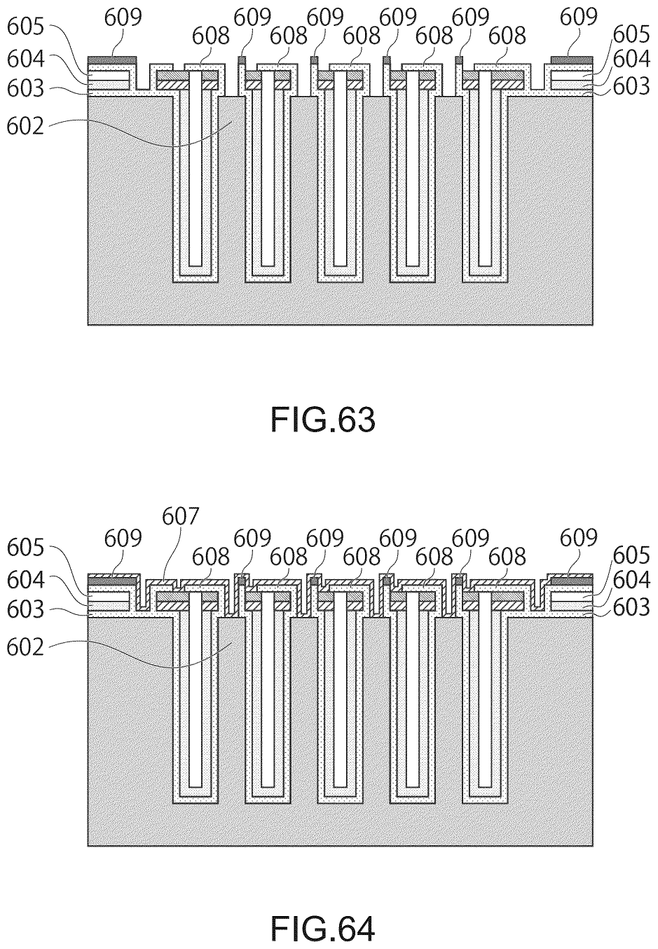

As shown in FIG. 63, in Step 214, the pattern of the cold point electrode 606 is formed by the photolithography described in the present specification.

As shown in FIG. 64, in Step 215, the electrode seed layer 607 is deposited by a method such as atomic layer deposition (ALD method), chemical vapor deposition method (CVD method), and an ion sputtering method. The film thickness of the electrode seed layer 607 can be suitably selected from the range of, for example, 1 to 100 nm. As the material forming the electrode seed layer 607, the material forming the electrode seed layer 607 described in the present specification can be appropriately selected. The deposition of the electrode seed layer 607 is not an essential Step and can also be omitted as appropriate.

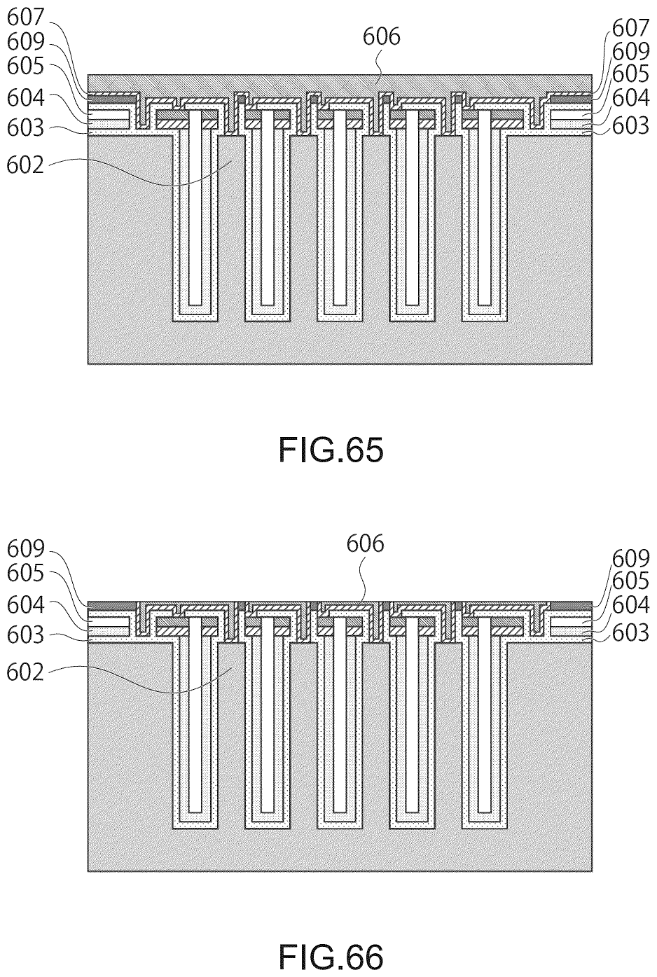

As shown in FIG. 65, in Step 216, the cold point electrode 606 is deposited by a method such as a plating method. As the material forming the cold point electrode 606, the material forming an electrode described in the present specification can be appropriately selected.

As shown in FIG. 66, in Step 217, the cold point electrode 606 is formed by surface flattening by chemical mechanical polishing (CMP).

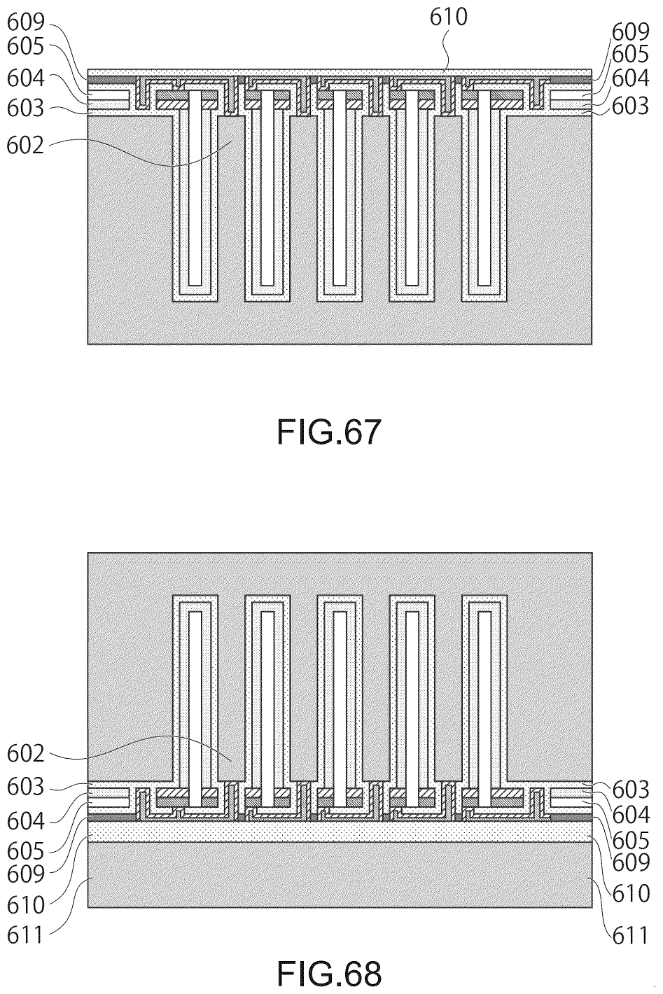

As shown in FIG. 67, in Step 218, a lower film 610 is deposited by a method such as atomic layer deposition (ALD method), chemical vapor deposition method (CVD method), and an ion sputtering method. The film thickness of the lower film 610 can be suitably selected from the range of, for example, 10 to 100 nm. The material forming the lower film 610 is not particularly limited as long as it does not affect the electrical properties of the cold point electrode 606. For example, the insulation material described in the present specification can be appropriately selected.

As shown in FIG. 68, in Step 219, the core layer substrate 601 that has undergone the above Steps is inverted and bonded to a support substrate 611 by an arbitrary method such as plasma activation bonding and room temperature bonding. Of the surfaces of the support substrate 611, the surface on the side to be bonded is favorably formed of a material that can be bonded to the lower film 610. Further, in this Step, bonding may be performed using the support substrate 611 provided with an extraction electrode described in the present specification in advance.

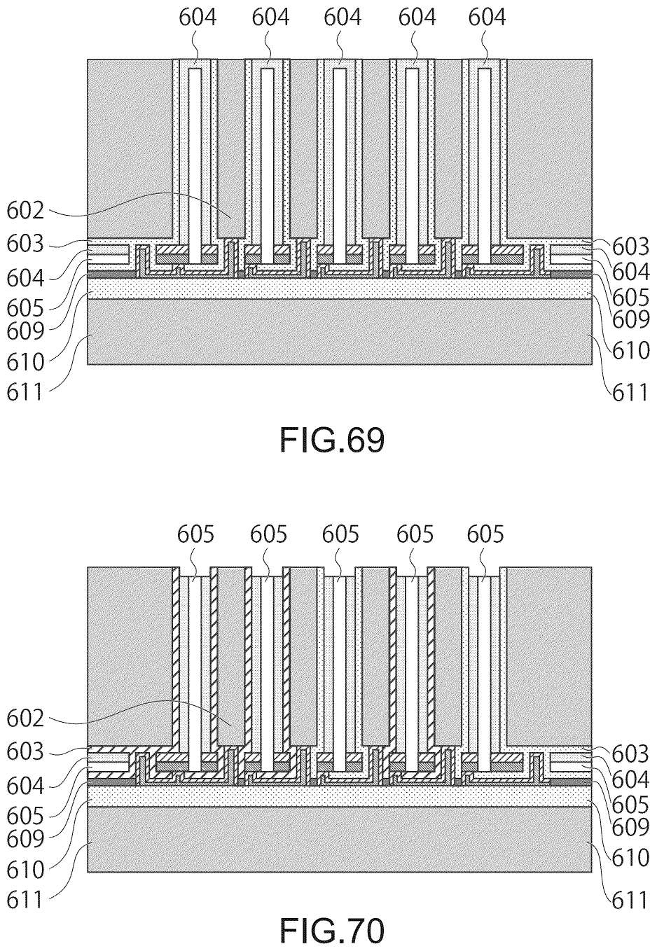

As shown in FIG. 69, in Step 220, the shell layer 604 is exposed by surface flattening by chemical mechanical polishing (CMP).

As shown in FIG. 70, in Step 221, anisotropic etching such as dry etching and wet etching is performed on the shell layer 604 to expose the insulation filling portion 605.

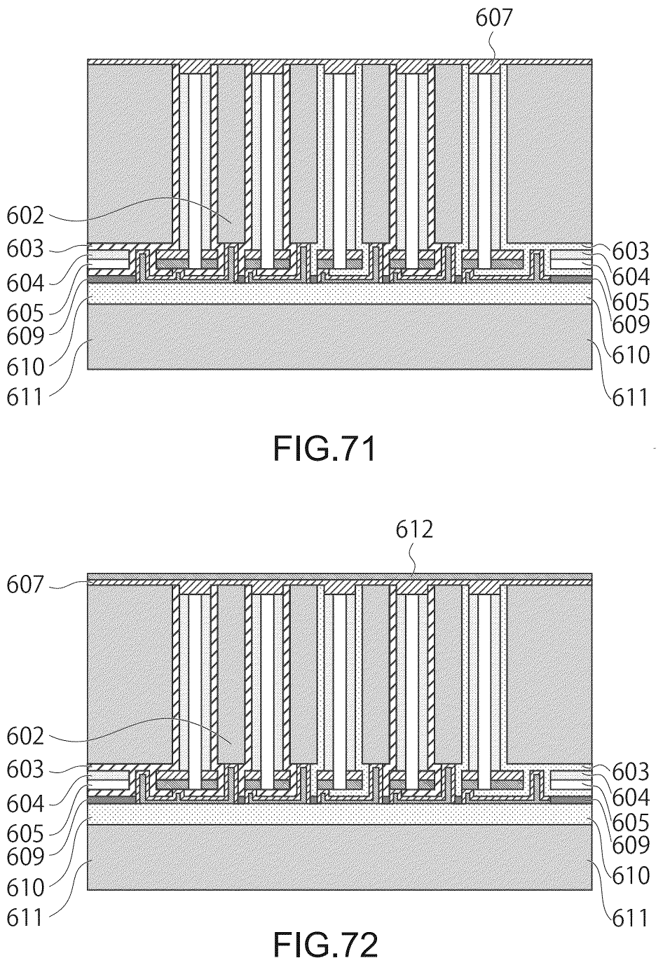

As shown in FIG. 71, in Step 222, the electrode seed layer 607 is deposited by a method such as atomic layer deposition (ALD method), chemical vapor deposition method (CVD method), and an ion sputtering method. The film thickness of the electrode seed layer 607 can be suitably selected from the range of, for example, 1 to 100 nm. As the material forming the electrode seed layer 607, the material forming the electrode seed layer 607 described in the present specification can be appropriately selected. The deposition of the electrode seed layer 607 is not an essential Step and can also be omitted as appropriate.

As shown in FIG. 72, in Step 223, a hot point electrode 612 is deposited by a method such as a plating method. As the material forming the hot point electrode 612, the material forming an electrode described in the present specification can be appropriately selected.

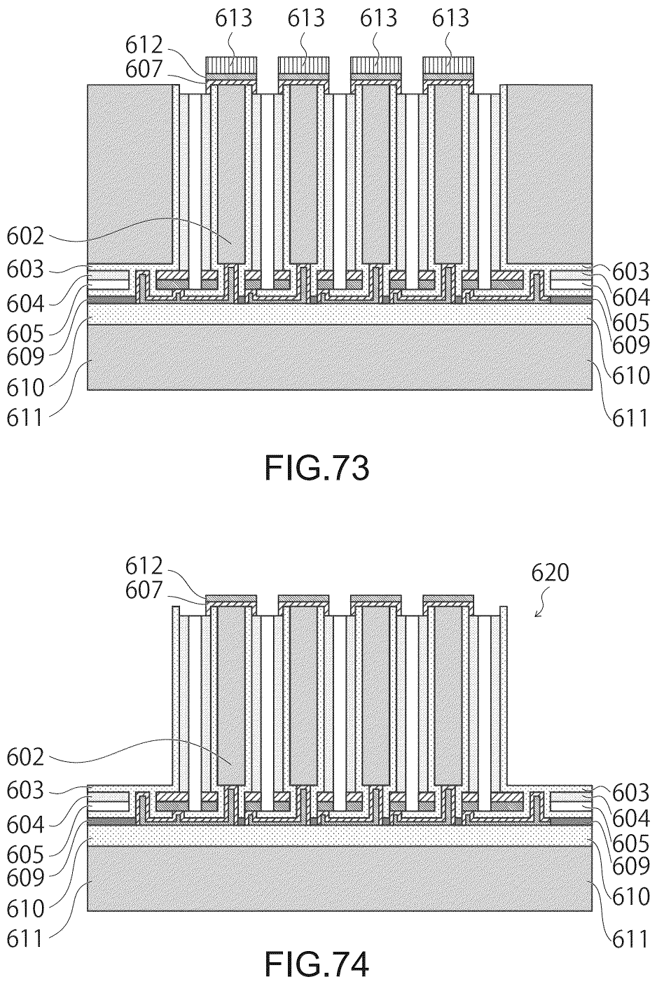

As shown in FIG. 73, in Step 224, the hot point electrode 612 is formed by the photolithography described in the present specification.

As shown in FIG. 74, in Step 225, after removing the portion of the core layer substrate 601 other than the portion corresponding to a thermoelectric conversion layer 620 by anisotropic etching such as dry etching, the material relating to the mask used in the photolithography treatment is removed by anisotropic etching treatment such as ashing treatment and dry etching.

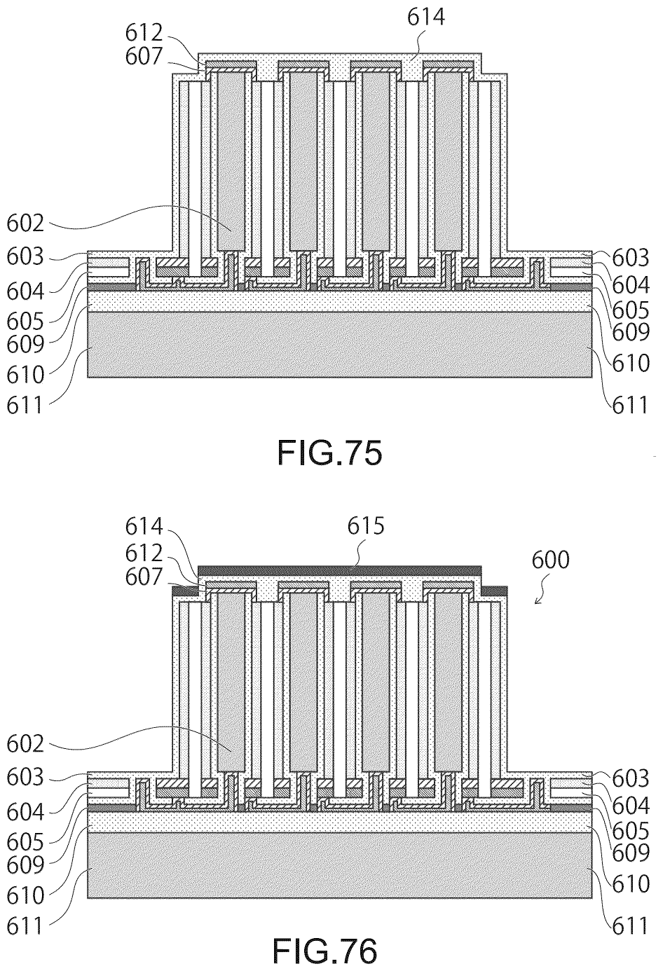

As shown in FIG. 75, in Step 226, an electrical insulation heat transfer body 614 relating to an absorption layer is deposited by a method such as atomic layer deposition (ALD method), chemical vapor deposition method (CVD method), and an ion sputtering method. As the material forming the electrical insulation heat transfer body 614, the insulation material described in the present specification can be appropriately selected. Further, the deposition of the electrical insulation heat transfer body 614 is not an essential Step and can also be omitted as appropriate in the case where an absorption portion 615 described below is a film with electrical insulation properties or a heat transfer film.

As shown in FIG. 76, in Step 227, the absorption portion 615 relating to an absorption layer is deposited by a method such as application, vapor phase growth, and spraying. In the case where the absorption portion 615 is a film with electrical insulation properties or a heat transfer film, the above-mentioned electrical insulation heat transfer body 614 does not necessarily need to be provided and the absorption portion 6115 may be in direct contact with the hot point electrode 612. Through the above Steps, the thermoelectric conversion element 600 is produced.

### (2) Example of Method of Producing Thermoelectric Conversion Element 700

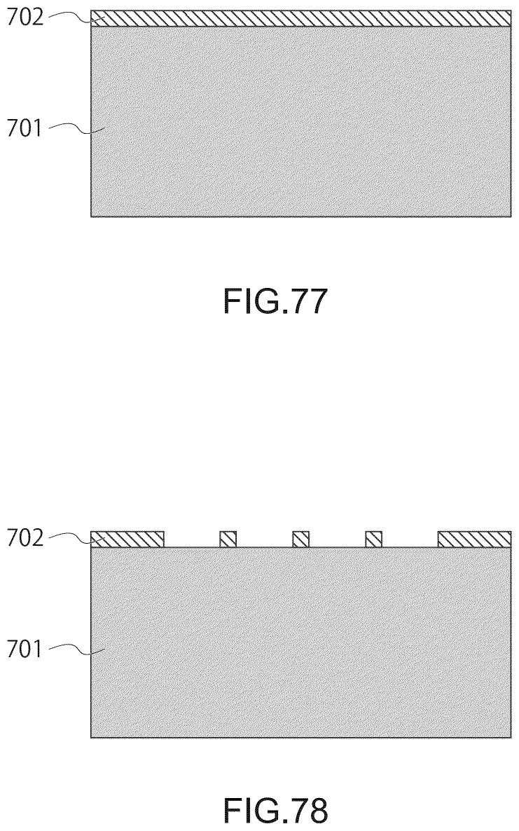

Next, an example of a method of producing a thermoelectric conversion element 700 according to this embodiment will be described with reference to FIGS. 77 to 99. FIGS. 77 to 99 are each a schematic diagram showing an example of the method of producing the thermoelectric conversion element 700. The production method according to this embodiment is a method of forming a hole for filling the center of a core-shell structure relating to a thermoelectric conversion layer in the initial stage of production.

In the method of producing the thermoelectric conversion element 700 according to this embodiment, in Step 301, as shown in FIG. 77, a shell layer substrate 701 is disposed. The shell layer substrate 701 serves as a shell layer of a core-shell structure relating to a thermoelectric conversion layer. As the material forming the shell layer substrate 701, any of the P-type thermoelectric material or the N-type thermoelectric material disclosed in the present specification may be selected. Further, a P-type thermoelectric material or an N-type thermoelectric material may be obtained by performing doping treatment with a material after forming the shell layer. The doping treatment method performed after forming the shell layer is not particularly limited, but can be performed by ion implantation, solution reaction, gas phase intercalation, liquid phase intercalation, or the like. The thickness of the shell layer substrate 701 is not particularly limited, and the shell layer substrate 701 can be suitably produced to have a thickness of, for example, 1 to 100 μm. Further, an insulation mold 702 is deposited on one surface of the shell layer substrate 701 by a method such as atomic layer deposition (ALD method), chemical vapor deposition method (CVD method), and an application deposition method. The film thickness of the insulation mold 702 can be suitably selected from the range of, for example, 10 to 100 nm. As the material forming the insulation mold 702, the insulation material described in the present specification can be appropriately selected.

Further, although the shell layer substrate 701 has a two-layer structure in which the material forming the above-mentioned shell layer substrate 701 is deposited on a silicon substrate, a quartz substrate, a sapphire substrate, or the like by an arbitrary method such as atomic layer deposition (ALD method) and chemical vapor deposition method (CVD method), the above-mentioned insulation mold 702 may be deposited on the surface on the side where the material forming the shell layer substrate 701 has been deposited. In this case, the shell layer substrate 701 has a three-layer structure.

After applying and depositing a photosensitive resist for photolithography on the surface of the shell layer substrate 701 by spin coating, prebaking treatment for removing the solvent from the applied resist film is performed. Note that ozone treatment or surface treatment using hexamethyldisilazane (HMDS) may be performed on the shell layer substrate 701 before depositing the resist film.

As shown in FIG. 78, in Step 302, the pattern of a cold point electrode 703 is formed by the photolithography described in the present specification.

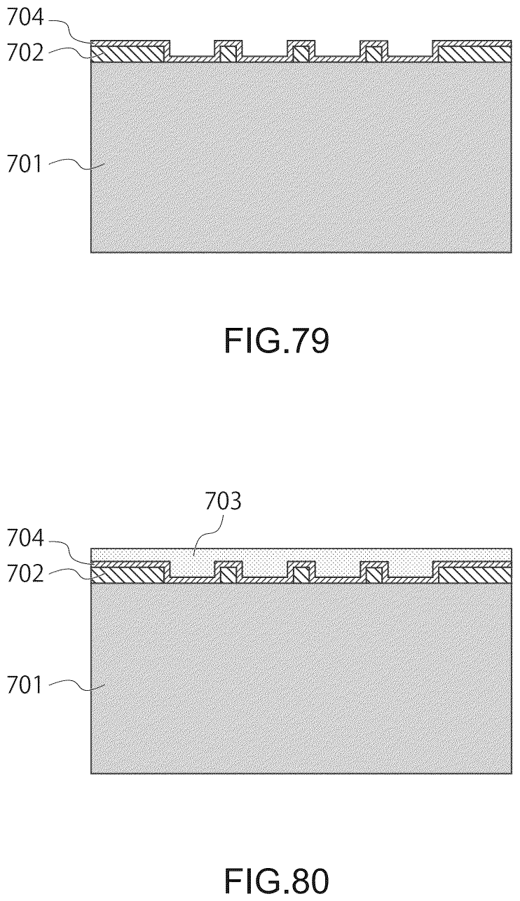

As shown in FIG. 79, in Step 303, an electrode seed layer 704 is deposited by a method such as atomic layer deposition (ALD method), chemical vapor deposition method (CVD method), and an ion sputtering method. The film thickness of the electrode seed layer 704 can be suitably selected from the range of, for example, 1 to 100 nm. As the material forming the electrode seed layer 704, the material forming the electrode seed layer 704 described in the present specification can be appropriately selected. The deposition of the electrode seed layer 704 is not an essential Step and can also be omitted as appropriate.

As shown in FIG. 80, in Step 304, the cold point electrode 703 is deposited by a method such as a plating method. As the material forming the cold point electrode 703, the material forming an electrode described in the present specification can be appropriately selected.

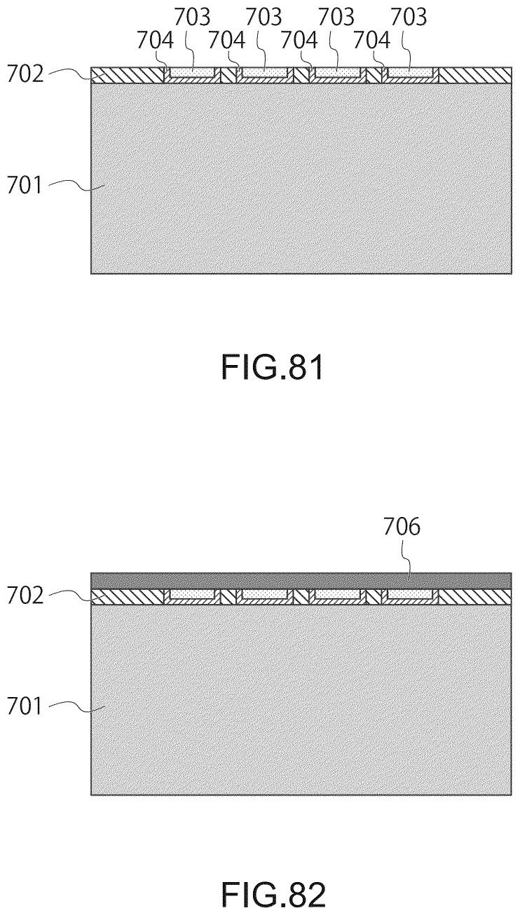

As shown in FIG. 81, in Step 305, the cold point electrode 703 is formed by surface flattening by chemical mechanical polishing (CMP).

As shown in FIG. 82, in Step 306, a cold point electrode insulating film 706 is deposited by a method such as atomic layer deposition (ALD method), chemical vapor deposition method (CVD method), and an ion sputtering method. The film thickness of the cold point electrode insulating film 706 can be suitably selected from the range of, for example, 10 to 100 nm. As the material forming the cold point electrode insulating film 706, a material different from the material used for the insulation mold 702, of the insulation materials described in the present specification, can be appropriately selected.

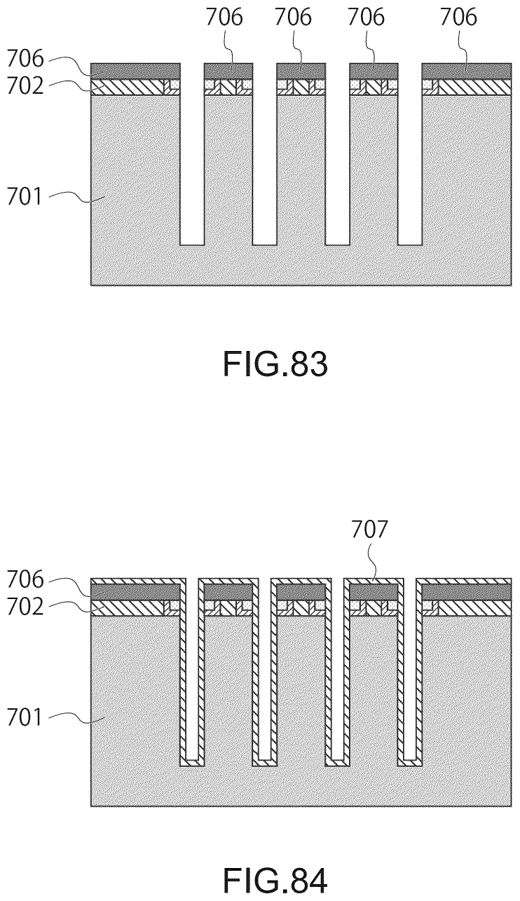

As shown in FIG. 83, in Step 307, a pattern of a hole shape for filling the center of the core-shell structure is formed by the photolithography described in the present specification. Note that the pattern of a hole shape favorably has a size such that the aspect ratio (height/pillar diameter) of a core layer 708 described below can be suitably selected from the range of, for example, 10 to 100 and the diameter of the core layer 602 can be suitably selected from the range of 100 to 5000 nm. Further, as the shape of the core layer 708, any of a columnar shape, a rectangular shape, and a polygonal columnar shape can be suitably used, similarly to the other embodiments.

As shown in FIG. 84, in Step 308, an insulation layer film 707 is deposited so as to follow the surface of the hole shape. As the method of depositing the insulation layer film 707, atomic layer deposition (ALD method), chemical vapor deposition method (CVD method), or the like can be appropriately selected. The film thickness of the insulation layer film 707 can be suitably selected from the range of, for example, 100 to 500 nm. As the material forming the insulation layer film 707, the insulation material described in the present specification can be appropriately selected.

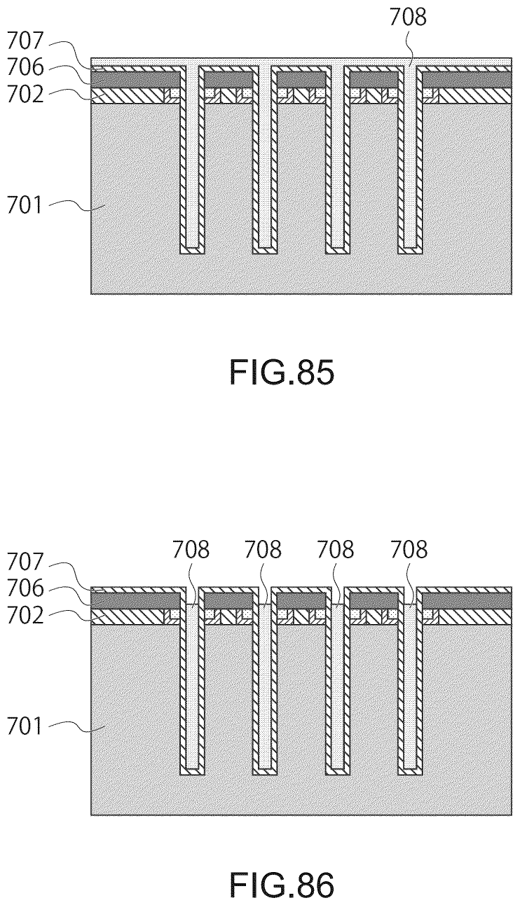

As shown in FIG. 85, in Step 309, the core layer 708 is deposited so as to follow the surface of the insulation layer film 707. As the method of depositing the core layer 708, atomic layer deposition (ALD method), chemical vapor deposition method (CVD method), an ion sputtering method, or a plating method can be appropriately selected. Further, as the material forming the core layer 708, a thermoelectric material of a type different from that of the shell layer substrate 701, of the P-type thermoelectric material and the N-type thermoelectric material described in the present specification, can be appropriately selected. This material may be used and deposited, but a P-type thermoelectric material or an N-type thermoelectric material may be obtained by performing the above-mentioned doping treatment after deposition.

As shown in FIG. 86, in Step 310, the core layer 708 exposed on the surface of the shell layer substrate 701 is removed by anisotropic etching such as dry etching and wet etching or chemical mechanical polishing (CMP).

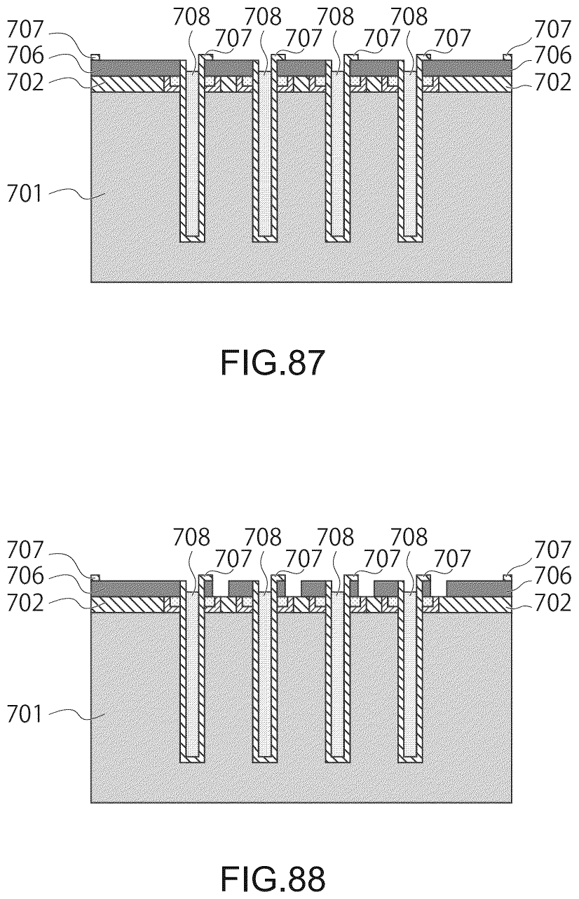

As shown in FIG. 87, in Step 311, the insulation layer film 707 is formed by anisotropic etching using dry etching or wet etching.

As shown in FIG. 88, in Step 312, the cold point electrode insulating film 706 is formed by anisotropic etching using dry etching or wet etching.

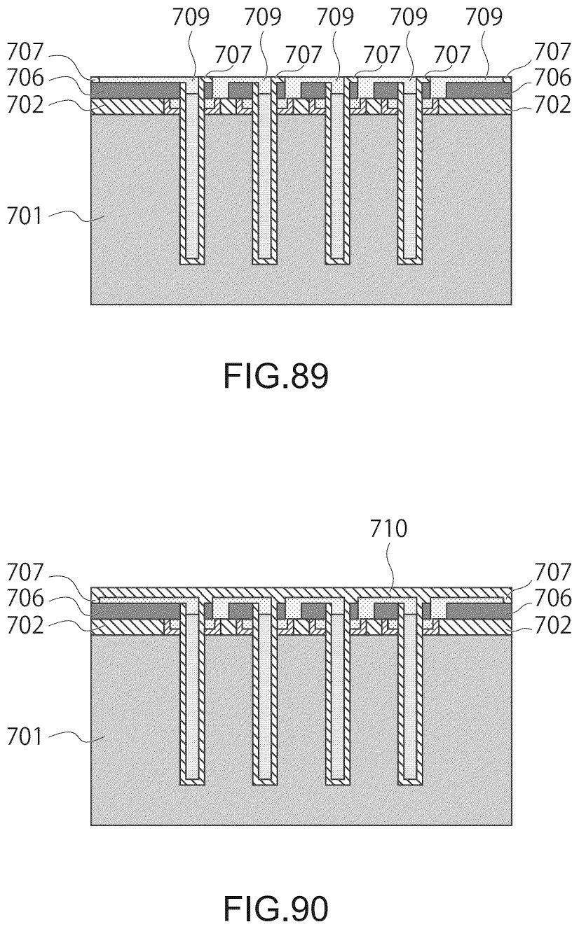

As shown in FIG. 89, in Step 313, after depositing a cold point electrode 709 by a method such as a plating method, the cold point electrode 709 is formed by surface flattening by chemical mechanical polishing (CMP). As the material forming the cold point electrode 709, the material forming an electrode described in the present specification can be appropriately selected. Further, the cold point electrode 709 may be deposited after depositing the electrode seed layer. As the material and deposition method of the electrode seed layer, the method described in the present specification can be appropriately selected.

As shown in FIG. 90, in Step 314, a lower film 710 is deposited by a method such as atomic layer deposition (ALD method), chemical vapor deposition method (CVD method), and an ion sputtering method. The film thickness of the lower film 710 can be suitably selected from the range of, for example, 10 to 500 nm. The material forming the lower film 710 is not particularly limited as long as it does not affect the electrical properties of the cold point electrode 709. For example, the insulation material described in the present specification can be appropriately selected.

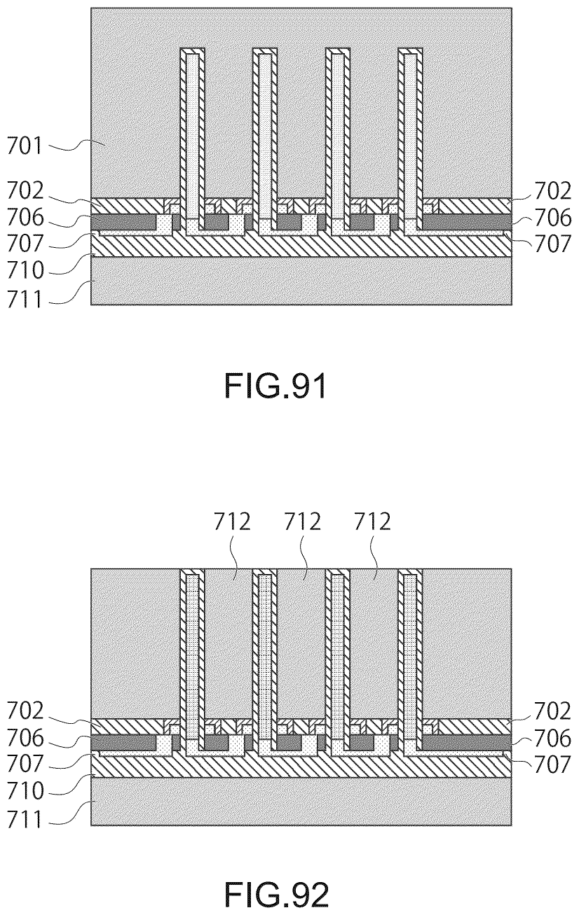

As shown in FIG. 91, in Step 315, the shell layer substrate 701 that has undergone the above Steps is inverted and bonded to a support substrate 711 by an arbitrary method such as plasma activation bonding and room temperature bonding. Of the surfaces of the support substrate 711, the surface on the side to be bonded is favorably formed of a material that can be bonded to the lower film 710. Further, in this Step, bonding may be performed using the support substrate 711 provided with an extraction electrode described in the present specification in advance.

As shown in FIG. 92, in Step 316, a shell layer 712 is exposed by surface flattening by chemical mechanical polishing (CMP).

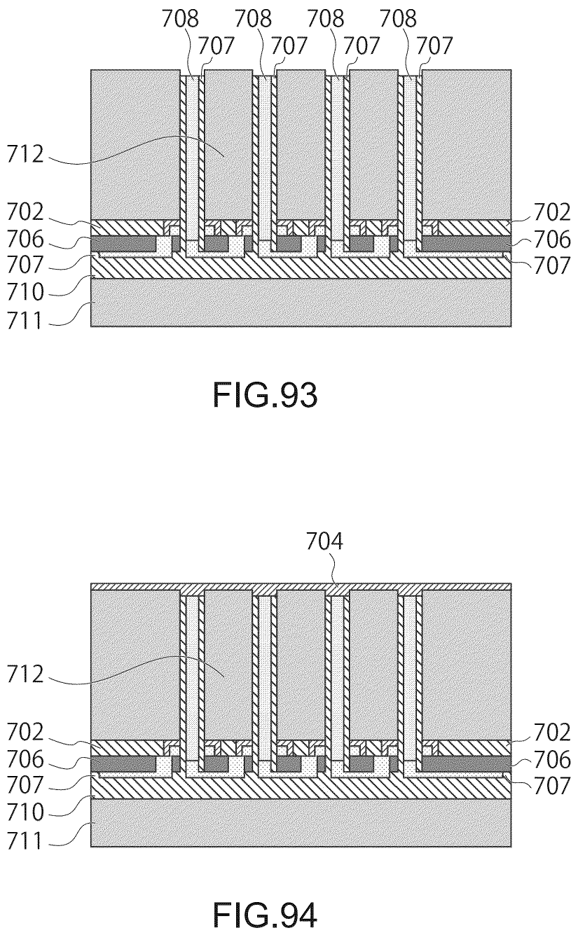

As shown in FIG. 93, in Step 317, anisotropic etching such as dry etching and wet etching is performed on the insulation layer film 707 to expose the core layer 708.

As shown in FIG. 94, in Step 318, the electrode seed layer 704 is deposited by a method such as atomic layer deposition (ALD method), chemical vapor deposition method (CVD method), and an ion sputtering method. The film thickness of the electrode seed layer 704 can be suitably selected from the range of, for example, 1 to 100 nm. As the material forming the electrode seed layer 704, the material forming the electrode seed layer 704 described in the present specification can be appropriately selected. The deposition of the electrode seed layer 704 is not an essential Step and can also be omitted as appropriate.

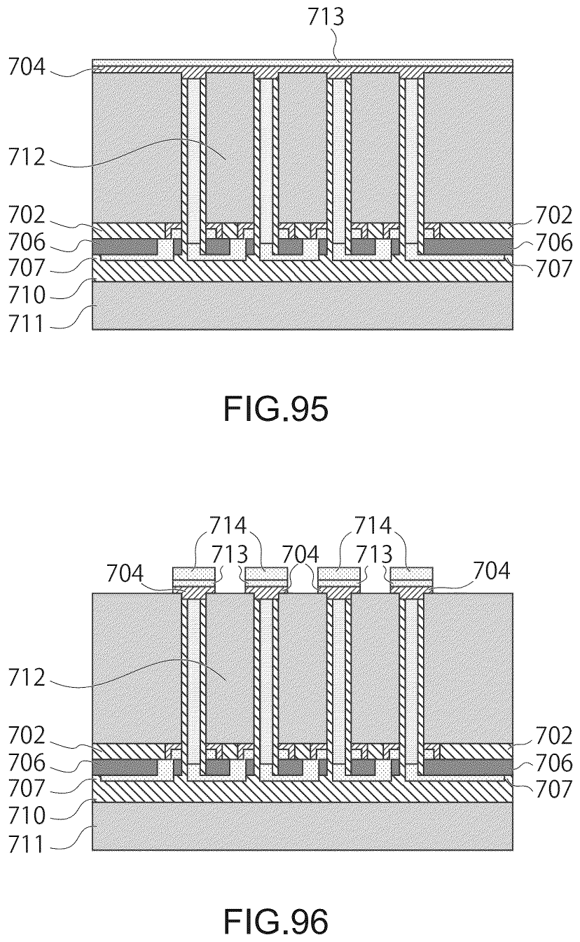

As shown in FIG. 95, in Step 319, a hot point electrode 713 is deposited by a method such as a plating method. As the material forming the hot point electrode 713, the material forming an electrode described in the present specification can be appropriately selected.

As shown in FIG. 96, in Step 320, the pattern of the hot point electrode 713 is formed by the photolithography described in the present specification.

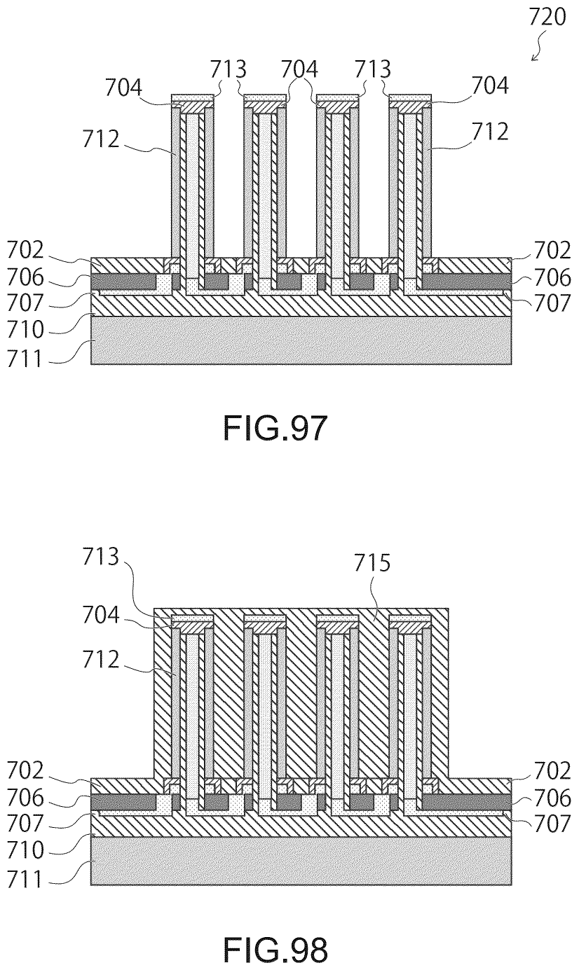

As shown in FIG. 97, in Step 321, after removing the portion of the shell layer substrate 701 other than the portion corresponding to a thermoelectric conversion layer 720 by anisotropic etching such as dry etching, the material relating to the mask used in the photolithography treatment is removed by anisotropic etching treatment such as ashing treatment and dry etching.

As shown in FIG. 98, in Step 322, an electrical insulation heat transfer body 715 relating to an absorption layer is deposited by a method such as atomic layer deposition (ALD method), chemical vapor deposition method (CVD method), and an application deposition method to fill the gap between the shell layer 712 and the shell layer 712. As the material forming the electrical insulation heat transfer body 715, the insulation material described in the present specification can be appropriately selected. Further, the deposition of the electrical insulation heat transfer body 715 is not an essential Step and, can also be omitted as appropriate in the case where an absorption portion 716 described below is a film with electrical insulation properties or a heat transfer film.

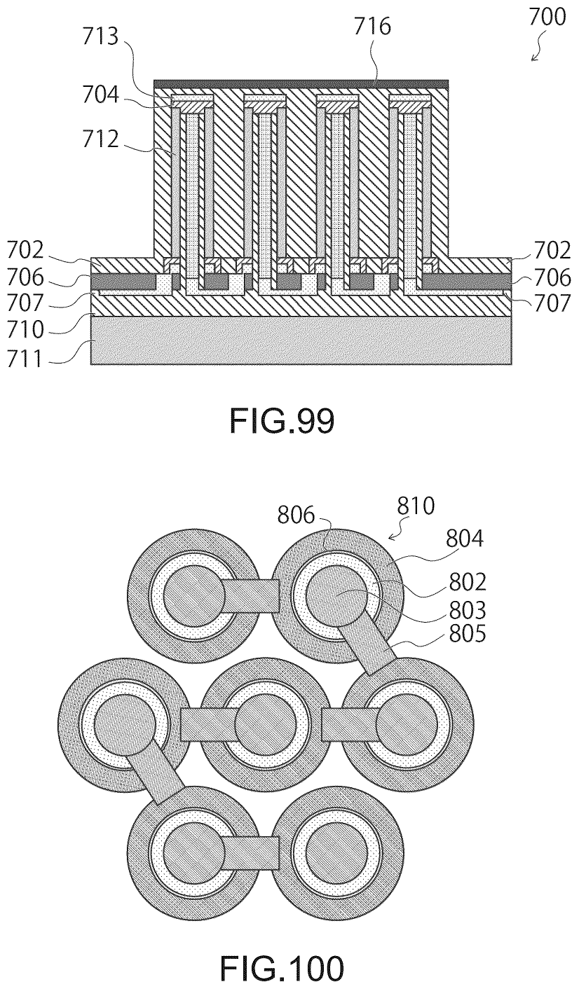

As shown in FIG. 99, in Step 323, the absorption portion 716 relating to an absorption layer is deposited by a method such as application, vapor phase growth, and spraying. In the case where the absorption portion 716 is a film with electrical insulation properties or a heat transfer film, the above-mentioned electrical insulation heat transfer body 715 does not necessarily need to be provided and the absorption portion 716 may be in direct contact with the hot point electrode 713. In this case, instead of the above-mentioned electrical insulation heat transfer body 714, the absorption portion 715 may be deposited in the gap between the shell layer 712 and the shell layer 712. Through the above Steps, the thermoelectric conversion element 700 is produced.

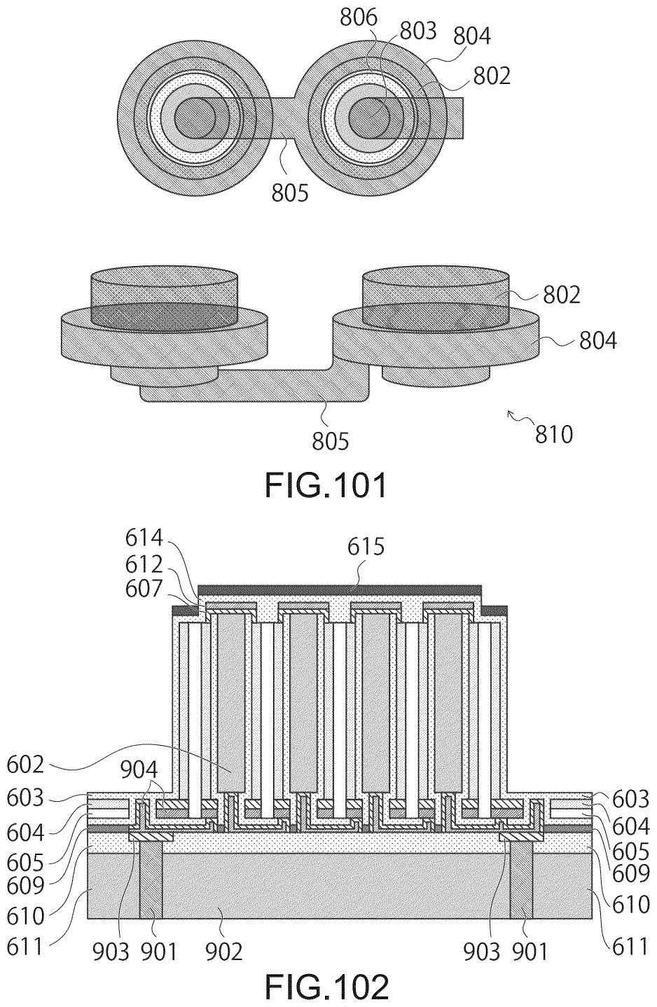

Next, the thermoelectric conversion layer of each of the thermoelectric conversion element 600 and the thermoelectric conversion element 700 will be described with reference to FIG. 100 and FIG. 101. FIG. 100 is a diagram showing the thermoelectric conversion element 600 and the thermoelectric conversion element 700 as viewed from the surface on the side of the cold point electrode. FIG. 101 is an enlarged schematic diagram of the core-shell pillar structure and the cold point electrode of each of the thermoelectric conversion element 600 and the thermoelectric conversion element 700.

As shown in FIG. 100, a core layer 801 of a core-shell pillar structure 810 and a shell layer 802 of the core-shell pillar structure 810 adjacent thereto are connected to each other via a core connection portion 803 of a cold point electrode, a core-shell connection portion 805, and a shell connection portion 804. Since the core layer 801 and the shell layer 802 constituting the core-shell pillar structure 810 are also connected to each other via a hot point electrode, a plurality of the core-shell pillar structures 810 is connected in PN series.

As shown in FIG. 101, in the thermoelectric conversion element 600 and the thermoelectric conversion element 700, the core layer 801 in one core-shell pillar structure 810 and the shell layer 802 in the core-shell pillar structure 810 adjacent thereto are electrically connected via the core connection portion 803 of the cold point electrode connected to the core layer 801, the core-shell connection portion 805, and then the shell connection portion 804.

Next, an embodiment in which the thermoelectromotive force generated in the thermoelectric conversion element is output from the lower part of the support substrate to the outside will be described with reference to FIG. 102. As shown in FIG. 102, in this embodiment, by providing an extraction electrode 901 so as to pass from the side where the core-shell pillar structure of a support substrate 902 is stacked to the opposite side, it is possible to output, from the power part side of the support substrate 902, the thermoelectromotive force generated in the thermoelectric conversion element. The extraction electrode 901 may be connected to a cold point electrode 904 via an electrode seed layer 903. Further, also in this embodiment, the electrode seed layer 903 does not necessarily need to be provided and can also be omitted as appropriate. This embodiment can be produced by, for example, using the support substrate 902 provided with the extraction electrode 901 in advance.

The present technology can be used as, for example, an image sensor by including a thermoelectromotive force generating element such as the thermoelectric conversion element according to each of the above embodiments and arraying the plurality of thermoelectromotive force generating elements in a direction in which the surface of the substrate spreads.

It should be noted that the present technology may take the following configurations.
(1) A thermoelectromotive force generating element, including:
   a substrate;
   a thermoelectric conversion layer that is stacked on the substate and includes a P-type thermoelectric material and an N-type thermoelectric material;
   a first electrode on a low temperature side connected to one end of the thermoelectric conversion layer;
   a second electrode on a high temperature side connected to the other end of the thermoelectric conversion layer; and
   an absorption portion that is stacked in contact with the second electrode and absorbs heat received from outside,
   the P-type thermoelectric material and the N-type thermoelectric material forming a PN series connection.
(2) The thermoelectromotive force generating element according to (1), in which
   the thermoelectric conversion layer is formed in a core-shell structure in which a periphery of one of the P-type thermoelectric material and the N-type thermoelectric material being covered and surrounded by the other.
(3) The thermoelectromotive force generating element according to (2), further including
   an insulation film for insulating an interface between the P-type thermoelectric material and the N-type thermoelectric material.
(4) The thermoelectromotive force generating element according to any one of (1) to (3), in which
   the thermoelectric conversion layer contains any of elements of C, Si, Ge, Sn, P, As, Sb, Bi, and Te, a mixture of any of the elements, or a compound represented by the following general formula (1), general formula (2), or general formula (3).

$${M}_{n} {Q}_{m} ( 0 < n \leq 2 , 0 < m \leq 3 ) \qquad ( 1 )$$

(in the formula, M represents any of C, Si, P, As, Sb, Te, Bi, Mg, Cu, Ag, Co, Ti, Zr, Hf, V, Nb, Ta, Mo, W, Sc, Mn, Fe, Ni, Cr, Pd, Pt, Re, Ga, Ge, Sn, Pb, Nb, and In, and
   Q represents any of C, Si, Ge, Sn, P, As, Sb, Bi, O, S, Se, and Te.)

$${L}_{X} {R}_{Y} {A}_{Z} {B}_{1 - Z} ( 0 < X \leq 1 ) , ( 0 \leq Y \leq 1 ) , ( 0 < Z \leq 1 ) \qquad ( 2 )$$

(in the formula, L or R represents any of Ti, Zr, Hf, V, Nb, Ta, Mo, W, Sc, Mn, Fe, Ni, Cr, Pd, Pt, Re, Cu, Zn, Ga, Ge, Sn, Pb, and In,
A represents any of N, O, P, S, Se, and Te, and
B represents any of N, O, P, S, Se, and Te.)

$$XYZ or {X}_{2} Y Z \qquad ( 3 )$$

(in the formula, X, Y, or Z represents any of Fe, Co, Ni, Cu, Zn, Ru, Rh, Pd, Ag, Cd, Ir, Pt, Au, Ti, V, Cr, Mn, Y, Zr, Nb, Hf, Ta, Al, Si, Ga, Ge, As, In, Sn, Sb, Ti, Pd, and Bi.)
(5) The thermoelectromotive force generating element according to (4), characterized in that
   the thermoelectric conversion layer further contains B, P, As, Sb, Al, or Ga.
(6) The thermoelectromotive force generating element according to any one of (3) to (5), in which
   the insulation film contains an oxide or nitride of a Group 14 element, or an organosilicon compound.
(7) The thermoelectromotive force generating element according to any one of (3) to (5), in which
   the insulation film contains SiO₂ or SiN_{X} (0<x<2).
(8) The thermoelectromotive force generating element according to any one of (1) to (7), in which
   the thermoelectric conversion layer includes a plurality of thermoelectric conversion layers, the thermoelectromotive force generating element further including an insulation filling portion for filling a gap between the thermoelectric conversion layers.
(9) The thermoelectromotive force generating element according to (8), in which
   the insulation filling portion is formed of a porous material.
(10) The thermoelectromotive force generating element according to any one of (1) to (9), in which
   the thermoelectric conversion layer has a columnar shape.
(11) The thermoelectromotive force generating element according to (10), in which
   the thermoelectric conversion layer has an aspect ratio (columnar height/diameter of a base circle) of 10 or more.
(12) The thermoelectromotive force generating element according to any one of (1) to (11), in which
   the absorption layer has electrical conductivity, the thermoelectromotive force generating element further including an electrical insulation heat transfer body that transfers heat to the second electrode.
(13) The thermoelectromotive force generating element according to any one of (1) to (12), in which
   the first electrode or the second electrode contains Au, Pt, Cu, Ag, Ni, Al, or graphene.
(14) The thermoelectromotive force generating element according to any one of (1) to (13), in which
   the first electrode or the second electrode further includes an electrode seed layer on a side to be connected to the thermoelectric conversion layer.
(15) The thermoelectromotive force generating element according to (14), in which
   the electrode seed layer contains Cr, W, Ti, Ta, Ni, or Mo, a nitride thereof, or a compound including a combination of Cr, W, Ti, Ta, Ni, and Mo.
(16) The thermoelectromotive force generating element according to any one of (1) to (15), in which
   the thermoelectromotive force generating element is a thermoelectric conversion element that generates thermoelectromotive force corresponding to an amount of heat absorbed from outside.
(17) The thermoelectromotive force generating element according to any one of (1) to (16), in which
   the absorption layer absorbs heat due to incident light, and
   the thermoelectromotive force generating element is an infrared photodetector.
(18) The thermoelectromotive force generating element according to any one of (1) to (17), in which
   thermoelectromotive force is output from an extraction electrode connected to the first electrode.
(19) The thermoelectromotive force generating element according to (18), in which
   the extraction electrode outputs the thermoelectromotive force from one of a side of the substrate where the thermoelectric conversion layer is stacked and a side of the substrate where the thermoelectric conversion layer is not stacked.
(20) A method of producing a thermoelectromotive force generating element, including:
   a step of forming a substrate;
   a step of forming a first electrode such that the first electrode is in contact with the substrate;
   a step of stacking a thermoelectric conversion layer that includes a P-type thermoelectric material and an N-type thermoelectric material such that the thermoelectric conversion layer is connected to the first electrode;
   a step of forming a second electrode such that the second electrode is connected to the other end of the thermoelectric conversion layer; and
   a step of stacking an absorption layer that absorbs heat received from outside such that the absorption layer is in contact with the second electrode,
   the P-type thermoelectric material and the N-type thermoelectric material forming a PN series connection.
(21) An image sensor, including:
   a plurality of the thermoelectromotive force generating elements according to any one of (1) to (19), the plurality of thermoelectromotive force generating elements being arrayed.

### REFERENCE SIGNS LIST

10, 30, 40, 100, 120, 200, 300, 320, 400, 500 a thermoelectric conversion element
11, 301 substrate
12, 31, 43, 212, 302, 321 thermoelectric conversion layer
13, 303, 606, 709, 904 cold point electrode (first electrode)
14, 44, 47, 48, 304, 322, 612, 713 hot point electrode (second electrode)
15, 112, 305, 410, 508, 615, 716 absorption portion
16, 111, 306, 409, 507, 614, 715 electrical insulation heat transfer body
21, 41, 311 P-type thermoelectric material
22, 42, 312 N-type thermoelectric material
23, 45, 46 insulation film
24, 605 insulation filling portion
32 gap
201 insulation substrate
202, 313 infrared reflective layer
314, 609, 702 insulation mold
600, 700 thermoelectric conversion element
601 core layer substrate
602, 708, 801 core layer
603, 707, 806 insulation layer film
604, 712, 802 shell layer
607, 704, 903 electrode seed layer
608, 706 cold point electrode insulating film
610, 710 lower film
611, 711, 902 support substrate
613, 714 resist pattern
620, 720, 810 thermoelectric conversion layer (core-shell pillar structure)
701 shell layer substrate
803 core connection portion of cold point electrode
804 shell connection portion of cold point electrode
805 core-shell connection portion of cold point electrode
901 extraction electrode

1. A thermoelectromotive force generating element, comprising:
a substrate;
a thermoelectric conversion layer that is stacked on the substate and includes a P-type thermoelectric material and an N-type thermoelectric material;
a first electrode connected to one end of the thermoelectric conversion layer;
a second electrode connected to the other end of the thermoelectric conversion layer; and
an absorption portion that is stacked in contact with the second electrode and absorbs heat received from outside,
the P-type thermoelectric material and the N-type thermoelectric material forming a PN series connection.

2. The thermoelectromotive force generating element according to claim 1, wherein
the thermoelectric conversion layer is formed in a core-shell structure in which a periphery of one of the P-type thermoelectric material and the N-type thermoelectric material being covered and surrounded by the other.

3. The thermoelectromotive force generating element according to claim 2, further comprising
an insulation film for insulating an interface between the P-type thermoelectric material and the N-type thermoelectric material.

4. The thermoelectromotive force generating element according to claim 1, wherein
the thermoelectric conversion layer contains any of elements of C, Si, Ge, Sn, P, As, Sb, Bi, and Te, a mixture of any of the elements, or a compound represented by the following general formula (1), general formula (2), or general formula (3).
$${M}_{n} {Q}_{m} ( 0 < n \leq 2 , 0 < m \leq 3 ) \qquad ( 1 )$$
(in the formula, M represents any of C, Si, P, As, Sb, Te, Bi, Mg, Cu, Ag, Co, Ti, Zr, Hf, V, Nb, Ta, Mo, W, Sc, Mn, Fe, Ni, Cr, Pd, Pt, Re, Ga, Ge, Sn, Pb, Nb, and In, and
Q represents any of C, Si, Ge, Sn, P, As, Sb, Bi, O, S, Se, and Te.)
$${L}_{X} {R}_{Y} {A}_{Z} {B}_{1 - Z} ( 0 < X \leq 1 ) , ( 0 \leq Y \leq 1 ) , ( 0 < Z \leq 1 ) \qquad ( 2 )$$
(in the formula, L or R represents any of Ti, Zr, Hf, V, Nb, Ta, Mo, W, Sc, Mn, Fe, Ni, Cr, Pd, Pt, Re, Cu, Zn, Ga, Ge, Sn, Pb, and In,
A represents any of N, O, P, S, Se, and Te, and
B represents any of N, O, P, S, Se, and Te.)
$$XYZ or {X}_{2} Y Z \qquad ( 3 )$$
(in the formula, X, Y, or Z represents any of Fe, Co, Ni, Cu, Zn, Ru, Rh, Pd, Ag, Cd, Ir, Pt, Au, Ti, V, Cr, Mn, Y, Zr, Nb, Hf, Ta, Al, Si, Ga, Ge, As, In, Sn, Sb, Ti, Pd, and Bi.)

5. The thermoelectromotive force generating element according to claim 4, characterized in that
the thermoelectric conversion layer further contains B, P, As, Sb, Al, or Ga.

6. The thermoelectromotive force generating element according to claim 3, wherein
the insulation film contains an oxide or nitride of a Group 14 element, or an organosilicon compound.

7. The thermoelectromotive force generating element according to claim 3, wherein
the insulation film contains SiO₂ or SiN_{X} (0<x<2).

8. The thermoelectromotive force generating element according to claim 1, wherein
the thermoelectric conversion layer includes a plurality of thermoelectric conversion layers, the thermoelectromotive force generating element further comprising an insulation filling portion for filling a gap between the thermoelectric conversion layers.

9. The thermoelectromotive force generating element according to claim 8, wherein
the insulation filling portion is formed of a porous material.

10. The thermoelectromotive force generating element according to claim 1, wherein
the thermoelectric conversion layer has a columnar shape.

11. The thermoelectromotive force generating element according to claim 10, wherein
the thermoelectric conversion layer has an aspect ratio (columnar height/diameter of a base circle) of 10 or more.

12. The thermoelectromotive force generating element according to claim 1, wherein
the absorption layer has electrical conductivity, the thermoelectromotive force generating element further comprising an electrical insulation heat transfer body that transfers heat to the second electrode.

13. The thermoelectromotive force generating element according to claim 1, wherein
the first electrode or the second electrode contains Au, Pt, Cu, Ag, Ni, Al, or graphene.

14. The thermoelectromotive force generating element according to claim 1, wherein
the first electrode or the second electrode further includes an electrode seed layer on a side to be connected to the thermoelectric conversion layer.

15. The thermoelectromotive force generating element according to claim 14, wherein
the electrode seed layer contains Cr, W, Ti, Ta, Ni, or Mo, a nitride thereof, or a compound including a combination of Cr, W, Ti, Ta, Ni, and Mo.

16. The thermoelectromotive force generating element according to claim 1, wherein
the thermoelectromotive force generating element is a thermoelectric conversion element that generates thermoelectromotive force corresponding to an amount of heat absorbed from outside.

17. The thermoelectromotive force generating element according to claim 1, wherein
the absorption layer absorbs heat due to incident light, and
the thermoelectromotive force generating element is an infrared photodetector.

18. The thermoelectromotive force generating element according to claim 1, wherein
thermoelectromotive force is output from an extraction electrode connected to the first electrode.

19. The thermoelectromotive force generating element according to claim 18, wherein
the extraction electrode outputs the thermoelectromotive force from one of a side of the substrate where the thermoelectric conversion layer is stacked and a side of the substrate where the thermoelectric conversion layer is not stacked.

20. A method of producing a thermoelectromotive force generating element, comprising:
a step of forming a substrate;
a step of forming a first electrode such that the first electrode is in contact with the substrate;
a step of stacking a thermoelectric conversion layer that includes a P-type thermoelectric material and an N-type thermoelectric material such that the thermoelectric conversion layer is connected to the first electrode;
a step of forming a second electrode such that the second electrode is connected to the other end of the thermoelectric conversion layer; and
a step of stacking an absorption layer that absorbs heat received from outside such that the absorption layer is in contact with the second electrode,
the P-type thermoelectric material and the N-type thermoelectric material forming a PN series connection.

21. An image sensor, comprising:
a plurality of the thermoelectromotive force generating elements according to claim 1, the plurality of thermoelectromotive force generating elements being arrayed.
